(19) United States
(12) Patent Application Publication
(10) Pub. No.: US 2016/0079560 A1
(43) Pub. Date: Mar. 17, 2016

(54) Electroconductive Support, OLED Incorporating It, and Manufacture of Same

(71) Applicant: Saint-Gobain Performance Plastics Corporation, Aurora, OH (US)

(72) Inventor: Denis Guimard, Paris (FR)

(21) Appl. No.: 14/850,591

(22) Filed: Sep. 10, 2015

(30) Foreign Application Priority Data
Sep. 11, 2014 (FR) 1458544

(51) Int. Cl. H01L 51/52; H01L 51/56

(52) U.S. Cl. CPC H01L 51/5237; H01L 51/56

(57) ABSTRACT

An electroconductive support can include a layer that defines a cavity, and a conductive strand within the cavity of the layer. The conductive strand can have an upper surface within a central zone and a side zone, wherein the upper surface has a surface roughness within the central zone that is rougher than a surface roughness within the side zone. The electroconductive can further include an electroconductive layer and a passivation layer overlying the conductive strand. The relatively smoother upper surface within the side zone can allow the width of the passivation layer to be relatively narrow and still achieve acceptable leakage current. A method of forming the electroconductive support can be performed using a wet chemical technique to form the conductive strand while suppressing roughness along a side zone of the upper surface of the conductive strand.

### CROSS-REFERENCE TO RELATED APPLICATION

The current application claims priority to French Patent Application No. 1458544, filed Sep. 11, 2014, entitled “Electroconductive Support for OLED, OLED Incorporating It, and Manufacture of Same”, naming as inventor Denis Guimard, which application is incorporated by reference herein in its entirety.

### FIELD OF THE DISCLOSURE

The present disclosure relates to an electroconductive support, an organic light-emitting device incorporating it and its manufacture.

### RELATED ART

Organic light-emitting diodes (OLED) traditionally include one or a stack of organic light-emitting materials supplied with electricity by two electrodes framing it generally in the form of electroconductive layers.

Traditionally, the upper electrode is a reflective metal layer for example made from aluminum, and the lower electrode is a transparent layer with a base of indium oxide, generally indium oxide doped with tin, better known under the abbreviation ITO, and with a thickness of 100 to 150 nm, and the sheet resistance of which is greater than 10-15 Ohm/sq. However, for uniform lighting over large surfaces (typically greater than 5×5 cm²), these sheet resistance values remain high and it is then necessary to associate the transparent layer (for example, ITO) with a grid either made from a multilayer metal of the MAM (Metal/Al/Metal) type, or a single layer, such as a silver grid made using printing techniques with a silver paste, in order to decrease the sheet resistance to values below 5 Ohm/sq, or even 1 Ohm/sq. These grids have a micronic thickness and have a width of approximately 100 μm.

The grid is next passivated in order to eliminate short-circuits (reduction of the leakage current) between the faults of the grid and the upper electrode (cathode).

This electrode with a passivated grid is expensive and complex to manufacture.

The manufacturing method remains to be simplified and made reliable on the industrial scale without penalizing the optical performance of the OLED device.

### BRIEF DESCRIPTION OF THE DRAWINGS

Embodiments are illustrated by way of example and are not limited in the accompanying figures.

FIG. 1 is a diagrammatic sectional view of an electroconductive support for an OLED according to a first embodiment of the invention, in which the central strand zone is under-flush with the top surface,

FIG. 1a a detail view of FIG. 1 without the passivation layer,

FIG. 1b is a diagrammatic top view of a metal grid usable in the support of FIG. 1, and FIG. 1c shows a top diagrammatic view of a metal grid usable in the support of FIG. 1,

FIG. 1d shows a diagrammatic detail view of a section of the cavity of the first partially structured layer with the strand of a grid deposited by PVD in a comparative example done by the Applicant,

FIG. 2 is a diagrammatic sectional view of an electroconductive support for an OLED according to a second embodiment of the invention, in which the first layer is completely structured,

FIG. 3 is a diagrammatic sectional view of the electroconductive support for an OLED according to a third embodiment of the invention, in which the passivation is between the central zone and the electroconductive coating,

FIG. 4 is a diagrammatic sectional view of an electroconductive support for an OLED according to a fourth embodiment of the invention, in which the grid is over-flush with the upper surface,

FIG. 5 is a diagrammatic sectional view of the electroconductive support for an OLED according to a fifth embodiment of the invention, in which the grid is flush with the surface of the electroconductive coating missing from the central zone,

FIG. 6 is a diagrammatic sectional view of an electroconductive support for an OLED according to a sixth embodiment, in which the grid is anchored in a first layer and a structured sublayer,

FIG. 6 is detailed view of FIG. 6′,

FIGS. 7a to 7i are diagrammatic views of the steps of the method for manufacturing the electroconductive support in relation with the first embodiment.

It is specified that out of a concern for clarity, the various elements of the depicted objects are not shown to scale.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

As used in this specification, when a deposition of a layer or coating (including one or more layers) is specified as being done directly below or directly on another deposition, this means that no other layer may be interposed between those two depositions.

As used in this specification, refractive indices are measured at 550 nm.

As used herein, a positive photoresist is a type of photoresist for which the part exposed to the radiation, such as UV or visible light, becomes soluble with respect to a developer (developing solution) and where the unexposed part of the photoresist remains insoluble with respect to the developer. A negative photoresist is a type of photoresist for which the part exposed to radiation, such as UV or visible light, becomes insoluble with respect to a developer and where the unexposed part of the photoresist remains soluble with respect to the developer.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

Group numbers corresponding to columns within the Periodic Table of Elements based on the IUPAC Periodic Table of Elements, version dated Jan. 21, 2011.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the electronic support and microelectronic arts.

A wet chemical process, such as electroless plating, can be performed to deposit a conductive material for a conductive strand. The conductive strand can be part of a grid for an electrochromic device, such as an organic light-emitting device. However, the wet chemical process may form an exposed surface of the conductive strand that can be relatively rough and may cause leakage current to be unacceptably high. Accordingly, a new method has been developed to form a new structure that allows for relatively lower leakage current and a narrower passivation layer over the conductive strand.

The new method can include forming a patterned masking layer over a first layer, wherein the patterned masking layer includes an opening. The first layer can be a layer overlying a substrate or may be the substrate, itself. The method can also include etching a cavity in the first layer below the opening such that a zone of the patterned masking layer is suspended over the cavity. The suspended zone can help to control roughness along a portion of an upper surface of the subsequently formed conductive strand. The method can further include depositing a conductive material within the cavity using a wet chemical deposition, and removing the patterned masking layer to form a conductive strand within the cavity. The conductive strand can have a side zone and a central zone, the side zone is defined by a portion of the conductive strand that was covered by the zone of the patterned masking layer, and the central zone was under the opening in the patterned masking layer when depositing the conductive material. In an embodiment, the portion of the upper surface of the conductive strand has a surface roughness within the central zone that is rougher than a surface roughness within the side zone. An electrode can be formed over the conductive strand, wherein the first electrode contacts the conductive strand along the upper surface of the conductive strand at least within the side zone, and in a particular embodiment, within the central zone, too. A passivation layer can be formed over the conductive strand.

In another embodiment, an electroconductive support can include a conductive strand can that has a central zone and a side zone, wherein an upper surface of the conductive strand has a surface roughness within a central region that is rougher than a surface roughness within a side zone. An electrode can overlie the conductive strand, wherein the electrode contacts the conductive strand along the upper surface of the conductive strand within the side zone, and in a particular embodiment, the central zone. A passivation layer overlies the conductive strand. The relatively smoother side zone allows the passivation layer to have a width that is narrower than if the conductive strand would have had a surface roughness across all of the conductive strand that would be the same as the central zone. Accordingly, the width of the passivation layer does not need to be 2 or more times as wide as the width of the conductive strand.

The conductive strand can include metal. In an embodiment, the conductive strand can be part of a grid. In another embodiment, the electroconductive support may include a plurality of conductive strands that are spaced apart, and in a finished electronic device, the conductive strands may be coupled to circuits.

The electroconductive support can be used in fabricating an electrochromic device such as an OLED, liquid crystal, or the like. In a particular embodiment, the electrochromic device can be in the form of a display and can be an active matrix display or a passive matrix display.

In an embodiment of the present invention, an electroconductive support for OLED, includes:

a (transparent) plastic substrate, preferably smooth, with refractive index n₁ in a range from 1.45 to 1.8, with a first main face, called first surface,

an electrode, which includes one or more conductive strands arranged in a grid, such as metal grid, made from metal material(s) (pure or alloy, preferably single layer or multilayer) having a resistance per square below 20Ω/□, better 10Ω/□, the conductive strands having a thickness e2 of at least 100 nm and preferably at most 1500 nm, the conductive strands (also called tracks) having a width A less than or equal to 50 μm, and being separated by an inter-strand distance B less than or equal to 5000 μm and at least 50 μm, the strands being separated by a plurality of non-electrically insulating non-electroconductive domains having a top surface further from the substrate, said domains preferably having a refractive index greater than 1.65.

The electroconductive support includes, on the side of the first surface, a first layer, preferably electrically insulating, with a given composition, with a refractive index n₃ of 1.70 to 2.3, preferably from 1.80 to 2.10 and in particular from 1.85 to 2.00, the first layer being directly on the first surface or on a moisture barrier layer, in one or multiple layers, mineral and (which is not an enamel), the first layer being partially or completely structured in terms of thickness with through holes or cavities, with a width Wc to at least partially anchor the conductive strands, the upper surface being the surface of the first layer or the surface of an overlayer, mineral, preferably electrically insulating (which is not an enamel), on the first layer, and with a thickness preferably no greater than 200 nm.

Along their length, the strands have a central zone between (planar) side zones that are flush with the upper surface and the surface roughness of the central zone is greater than the surface roughness of the (smooth) side zones, the roughness parameter Rq of the side zones preferably being no more than 5 nm.

The electroconductive support further comprises:

an electroconductive coating made from an organic or preferably mineral material (single or multi-materials) which covers, preferably directly, the top surface and is above the side zones and electrically connected with the side zones, optionally is present above the central zones and electrically connected with central zones, with a thickness e₅ less than or equal to 800 nm, with a resistivity ρ₅ of less than 20 Ω·cm and greater than the resistivity of the conductive strands, and which has a refractive index n₅ of at least 1.5, better still at least 1.55, and even at least 1.7.

Additionally, in the central zone, the middle of the strand surface and the top surface are separated by a vertical distance H taken at the normal to the first surface and which is less than or equal to 500 nm, better still less than or equal to 300 nm, and even less than or equal to 100 nm when the central zone is over-flush with the top surface.

The conductive strands (its central zone) is preferably at least partially anchored in the first layer and optionally completely anchored in a potential electrically insulating upper layer (single layer or multilayer) on the first layer. An upper surface—surface of the first layer or optional overlayer—is chosen to be as smooth as possible so as to reduce the leakage current. Advantageously, the first layer whose surface optionally forms the top surface is partially structured in terms of thickness and is stripped of diffusing particles and/or the overlayer, which is completely structured in terms of thickness and the surface of which forms the top layer, is stripped of diffusing particles, and even the first layer is stripped of diffusing particles.

The top surface (of the first layer or overlayer) may preferably have a roughness Rq of less than 10 nm, better less than 5 nm, and even less than 2 nm. Rq may be defined according to standard ISO4287 and measured by atomic force microscopy.

The value of H is limited to 500 nm in under-flushness so as to minimize the abruptness as much as possible. The over-flushness is reduced as much as possible to anchor the layer and allow passivation of the grid flanks by the electroconductive domains.

The first layer may be polymeric. It is a deposit or transparent film (high index), in particular thermoplastic, such as PEN (polyethylene naphthalate). Its refractive index is approximately 1.75.

Examples of the moisture bather include the steps described in WO2011029786 and WO2011029787, which is incorporated herein by reference in its entirety.

Preferably, the roughness parameter Rq (of the surface) of the (planar) side zones is at most 5 nm and even at most 3 nm, and even the most 2 nm or even 1 nm. Preferably, the Rmax (maximum height) in each (planar) side zone is at most 20 nm, and even at most 10 nm.

The roughness of the upper central zone at the surface roughness of the side zones is in particular obtained for a deposit of the grid material via a wet chemical method, such as electroless deposit (by silvering, etc.). The roughness of the central zone increases with the thickness of the conductive strands (the smooth nature of the side zones is independent of the thickness).

The roughness parameter Rq (or rms) in the central zone may be at least 10 nm and even at least 20 nm, and preferably at most 60 nm. Additionally, even the roughness parameter Rmax (maximum height) in the central zone may be at least 100 nm and even at least 150 nm, and preferably at most 500 nm.

Rmax and Rq may be defined according to standard ISO4287 and measured by atomic force microscopy.

According to an embodiment of the invention, a side zone flush with the upper surface may be strictly on the same plane as the upper layer or separated therefrom by at most 10 nm, and better by at most 5 nm.

The fact that each (planar) side zone is flush with the upper surface also occurs due to wet chemical deposition of the metal, such as electroless deposition, based on the production of a metal salt in solution, deposition done through openings of a masking layer on a (partially or completely) structured layer by wet etching. This flushness phenomenon is independent of the thickness of the metal.

In particular, in the example of an electroless deposit such as silvering, the metal, such as silver, copper, nickel, or the like, is deposited in the holes of a layer that is (partially or completely) structured (overlayer alone, or overlayer and first layer). The holes are wider than the openings of the masking layer due to the lateral etching that occurs during the formation of the structured layer by wet etching. The metal is deposited on the flanks and the inner surface of the masking layer that is situated above each hole, inner surface in the plane of the top surface and therefore exceeding the flanks of each hole.

The side zones flush with the top surface are planar, smooth due to their contact with the masking layer, which in turn has a smooth inner surface. The inner surface reproduces the smooth, planar nature of the upper surface. The wet etching does not generate significant roughness on the inner surface and the smooth flanks and cavity bottoms (this roughness that may be generated does not increase the roughness of the grid surface relative to a deposition on a smooth surface).

During a physical vapor deposition (PVD), such as magnetron cathode sputtering, by shadow effect through the openings of the masking layer such as a photoresist, the side zones of the strands are in a basin, forming a morphological rupture with a depth equivalent to the height of cavities of the (partially or completely) structured layer that may generate short-circuits when the OLED is subsequently manufactured. In this type of deposition, the strand has no smooth side zone flush with the top surface for an under-flush or over-flush conductive strand. An under-flush strand has an upper surface in the center zone that lies at an elevation below a primary surface the layer in which it resides, and an over-flush strand has an upper surface in the in the center zone that lies at an elevation above a primary surface the layer in which it reside

Furthermore, the electroless deposition is simple, less complex (no vacuum installations, etc.) than physical vapor deposition (PVD), and is suitable for any substrate size. Furthermore, the electric conductivity of the metal deposited by electroless deposition is sufficiently low (typically 30% to 40% less than that of the same metal deposited by PVD).

H Influence

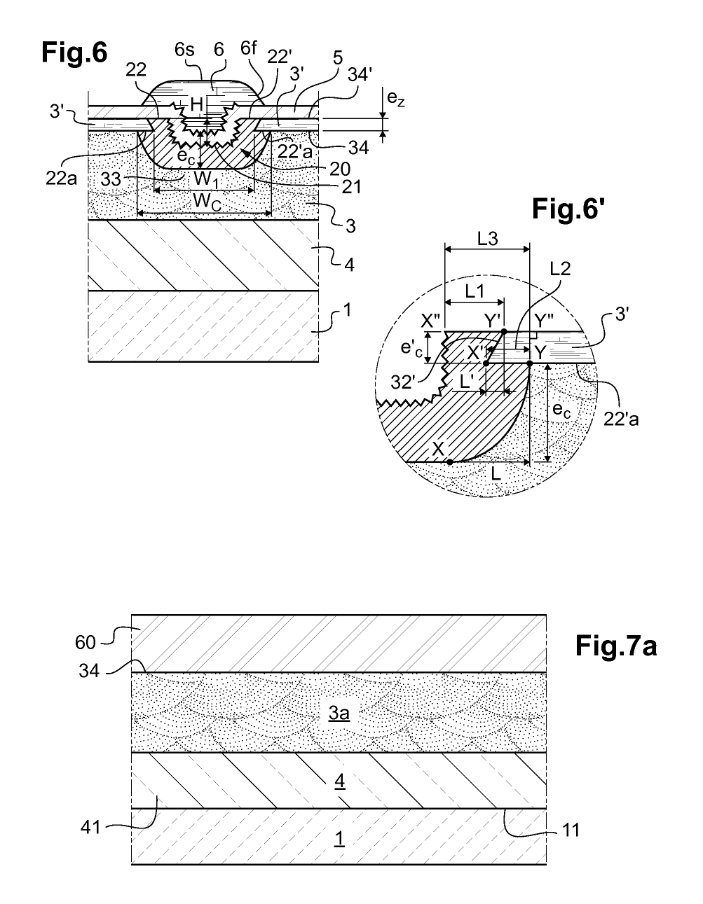

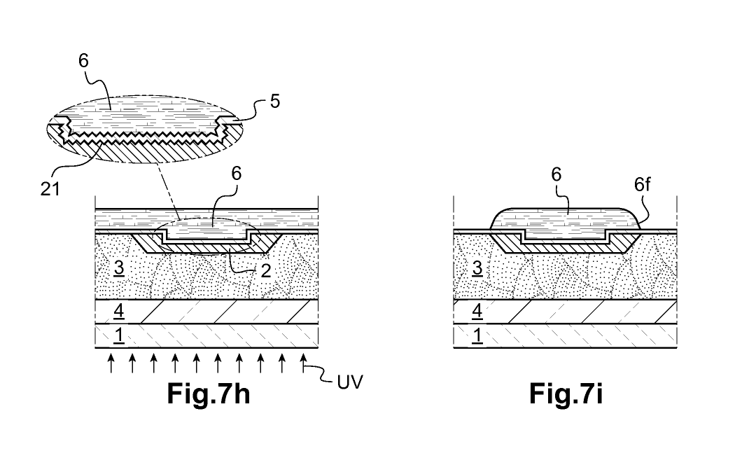

H is the elevational difference between the upper surface of a conductive strand within center zone and the primary surface of the layer in which the conductive strand is formed. See FIGS. 4 and 7e for reference. In one embodiment that is preferred because it is reliable and the easiest to manufacture, the central zone is under-flush with the upper surface, and H is greater than 100 nm, even greater than 150 nm.

During tests, the Applicant has observed the interest of a sufficient gap between the surface of the conductive strand in the central zone and the top surface. In fact, in the case of over-flush conductive strand, or under-flush conductive strand with lower values of H, the Applicant has observed the appearance of metal protuberances with a height H1 of approximately 20 nm to 200 nm and width W1 at half-height of 20 nm to 500 nm running along the inner edges of the side zones. These protuberances are continuous or discontinuous. These protuberances are detrimental because they may increase the leakage current. The gap H greater than 100 nm, even greater than 150 nm according to an embodiment of the invention, makes it possible to significantly reduce these protuberances and their height, or even to eliminate them.

According to an embodiment of the invention, when the conductive strands is under-flush with the upper surface, with H greater than 100 nm, better still greater than 150 nm, the majority of the metal strands and even each metal strand according to an embodiment of the invention being stripped of these protuberances. According to an embodiment of the invention, the metal strand surface, preferably silver, is considered to be stripped of protuberances when those protuberances running along the inner edges of the side zones have a height of less than 10 nm.

In another embodiment, H is less than or equal to 100 nm, and even preferably the central zone is under-flush with the upper surface, preferably the conductive strand surface is stripped of (metal) protuberances with a height greater than 10 nm running on the inner edges (central zone side) of the side zones.

With a low gap H, the protuberances are generated during the removal of the masking layer. It is assumed that when the gap H is small (quasi-flush strands), the rupture between the metal of the conductive strand (e.g., silver) deposited in the hole of the (partially or completely) structured layer and that on the flanks of the masking layer is more delicate to perform due to a larger contact zone between the conductive strands and that on the masking layer. However, these protuberances may be eliminated by chemical etching.

Advantageously, the electroconductive support may include a discontinuous passivation layer made from electrically material, forming a grid of isolating tracks located above the central zones and optionally above the side zones of the strands, completely covering the central zones and optionally partially or completely covering the side zones and not protruding laterally from the outer edges of the strands (above the top surface) or protruding laterally from the outer edges of the strands by no more than 1 μm, or no more than 500 nm, or no more than 200 nm (above the top surface), or even not protruding from the central zones.

In the support according to an embodiment of the invention, the electric insulation of the central zones of the strands situated above the electroconductive coating makes it possible to increase the measured external quantum efficiency (EQE) relative to a non-passivated conductive strand like that the aforementioned prior art. In the case of a non-passivated conductive strand, the carriers injected above the conductive strand generate photons that are subsequently absorbed by the conductive strand. In the case of the passivated grid (without the electroconductive coating of the passivation layer), there are no charge carriers injected above the conductive strand, therefore lost photons.

Furthermore, the passivation layer, which may be in the form of an insulating grid according to an embodiment of the invention, may optionally make it possible to limit the leakage current, and therefore, the deterioration of the lifetime of the OLED due to the absence of current lines above the rough central zones (central zones becoming electrically inactive assuming current lines perpendicular to the plane of the substrate) can be reduced. Similar effects may be seen with other electronic devices. If additionally the surface of the passivation layer is smooth (for example, a layer obtained by sol gel or other wet chemical method), it may planarize major leak current source faults.

The conductive strands have a small width A that may even be invisible, unlike MAM grids. Additionally, the passivation is localized above strands, unlike the passivation of the MAM grids generating a lateral excess of the sides of the grid of approximately 50 μm, or even greater than 50 μm. Given that the insulating tracks do not extend laterally beyond the metal strands (or little, exceeding by less than 1 μm), the insulating tracks do not cause a lighted surface loss, or little such loss, given the ratio between the strand widths and the possible lateral protrusion according to an embodiment of the invention).

The presence of the side zones smoother than the central zone further procures a major advantage of the support according to an embodiment of the invention. The side zones do not need to be passivated themselves (since they are smooth). The manufacturing method according to an embodiment of the invention makes it possible to locate the insulating tracks partially or completely on the side zones, and thus to completely cover the rough central zones. Given that the side zones are smooth and do not generate leakage current, their overlap, which is optionally only partial, is not bothersome. The possibility of only partial overlap also makes it possible to offer an advantage in terms of manufacturing method, by imparting an allowance in the choice of the method parameters.

The larger they are, the greater the tolerance is. The passivation layer can, therefore, completely or partially cover the side zones as long as the central zones are completely covered.

The width of the central zone may be greater than, equal to or less than that of each side zone (defined at the upper surface). This depends on e₂, H and the width of the holes through which conductive material passes into the cavities.

Preferably, the passivation layer has, above the central zone, an upper surface that has a roughness parameter Rq of less than 10 nm, better less than 5 nm, and even less than 2 nm, and even a roughness parameter Rmax of less than 100 nm, better less than 500 nm, and even less than 20 nm. Additionally, the passivation layer preferably has flanks with a roughness parameter Rq of less than 10 nm, even less than 5 nm, and better still less than 2 nm, and even a roughness parameter Rmax of less than 100 nm, better still less than 50 nm, and even less than 20 nm.

The passivation layer may be single layer or multilayer, transparent or opaque (more or less absorbent), and may have any refractive index.

The passivation layer may be organic, in particular polymeric.

In a first embodiment of the passivation, the electrically insulating material is a positive (annealed) photoresist, with a thickness e₆ of less than 1000 nm, even at most 600 nm, and even at most 300 nm on the electroconductive coating.

The passivation layer may be a single layer or multilayer, transparent or opaque (more or less absorbent), and may have any refractive index.

The passivation layer can have oblique flanks caused by the development of the positive photoresist. In particular, the base of the insulating tracks may have an angle α of no more than 60°, or between 40° and 50°, with the upper surface such that the insulating tracks have a decreasing width moving away from the first surface. The section of the passivation layer is typically dome-shaped, without sharp angles.

The thickness of the planarization material is preferably approximately the value of Rmax of the conductive strands.

In one preferred form of this first embodiment, the passivation layer is a layer with a base of one of the following materials: a polyimide, a polysiloxane, a phenyl formaldehyde (known under the name novolac), or a polymethyl methacrylate (PMMA).

In a second embodiment, the passivation layer is mineral, and more particularly an oxide layer preferably by sol gel and/or a nitride of a material that is a metal and/or silicon and preferably a layer of silicon or titanium nitride, or titanium, zirconium, silicon, niobium oxide, and mixtures thereof.

The material of the insulating tracks may be deposited using different methods (for example, cathode sputtering, sol gel). Three configurations may be used for the passivation layer.

In a first configuration, the passivation layer is on the electroconductive coating, preferably mineral.

In a second configuration, the passivation layer is between the electroconductive coating, preferably mineral, and the central zone (and even the side zones).

In a third configuration, the electroconductive coating, preferably with a base of indium, is discontinuous, missing from the central zones, and the passivation layer is for example covered by a hole injection layer (HIL) or a hole transport layer (HTL) that can be a polymeric layer, such as 3,4-polyethylenedioxythiophene (PEDOT).

The electroconductive coating may be discontinuous, missing from the central zones, and H is then defined between the middle of the strand surface and the surface of the electroconductive coating.

The first layer may be polymeric (high refractive index).

To have as smooth a surface as possible, it is preferable for the first, optionally partially structured, layer to have few or no diffusing particles, and even not to have a (significant) diffusing function.

The first layer may be an oxide layer, preferably by sol gel and/or nitride, of a material that is a metal and/or silicon, and preferably a layer of silicon nitride, titanium nitride, or titanium oxide, zirconium oxide, silicon oxide, and mixtures thereof, or a conductive transparent oxide, in particular zinc-based.

The first, optionally partially structured, layer according to an embodiment of the invention may have a large surface, for example a surface greater than or equal to 0.005 m², or even greater than or equal to 0.5 m² or 1 m². When in the form of a grid, the grid according to an embodiment of the invention may cover a large surface, for example a surface greater than or equal to 0.02 m², or even greater than or equal to 0.5 m² or 1 m².

It is possible to add a moisture barrier layer on the substrate that may be a plastic substrate. The barrier layer may have a base of silicon nitride, silicon oxycarbide, silicon oxynitride, silicon oxycarbonitride, or silica, alumina, titanium oxide, tin oxide, aluminum nitride, titanium nitride, for example with a thickness of less than or equal to 10 nm and preferably greater than or equal to 3 nm, or even 5 nm. It may involve a multilayer.

Regarding the conductive strands, the strands are elongated—separate or preferably interconnected (at least in the light-emitting region), in particular the mesh. The insulating tracks have the same architecture.

Preferably, the conductive strands are formed by electroless deposition, and preferably by silvering.

Advantageously, the conductive strands according to an embodiment of the invention may have a sheet resistance less than or equal to 10 Ohms/square, preferably less than or equal to 5 Ohms/square, and even 1 Ohm/square.

The material(s) of the conductive strands are chosen from the group formed by silver, copper, nickel, in particular pure material, or may be an alloy with a base of these materials. The conductive strands preferably have a silver base.

The conductive strands may preferably be single layer (silver) or multilayer (preferably with at least 80%, even 90% silver).

The conductive strands may be multilayer, in particular silver multilayer, and comprise (or be made up of), in the following order:

a first metal layer (directly on the bottom of the cavities or metal layer closest to the bottom of the cavities), preferably made from a first metal material, which preferably has a base of silver or is made from silver, forming less than 15% and even 10% of the total thickness e₂ of the grid and/or at least 3 nm, 5 nm or even at least 10 nm, and preferably less than 100 nm or even 50 nm,

a second metal layer (on the first layer, moving away from the substrate), in particular with a discernible interface with the first layer, with a base of a second metal material that is preferably chosen from among silver, aluminum or copper, forming at least 70%, 80% and even 90% of the total thickness e₂ of the grid of the second layer, which preferably has a base of silver or is made from silver, in particular like the first layer.

It is in particular possible to form a first metal layer with a base of silver according to the first deposition method, for example deposited by silvering, preferably with a thickness of at least 20 nm, and even at least 30 nm, or by vacuum deposition (sputtering), and a second metal layer with a base of silver having a thickness of at least 3 nm or even 5 nm, using a second deposition method, preferably, which is electroless deposition. The advantage of electroless deposition is a greater silver usage rate than silvering and a less expensive method than sputtering.

The conductive strands may be multilayer with layers of different materials, for example with a last anti-corrosion layer (water and/or air), for example metal, made from a different material from the underlying metal layer, in particular different from silver, with a thickness smaller than 10 nm, better still smaller than 5 nm, or even 3 nm. This layer is in particular useful for a silver-based grid.

The conductive strands may further be multilayer with two layers of different materials, for example bilayer, and made up of:

a (single) middle layer made from the aforementioned materials, preferably with a base of silver, with a thickness of preferably at least 100 nm, for example deposited by silvering or vacuum deposition (sputtering), and

an overlayer protecting against corrosion (water and/or air), for example made from metal, from a material different from the metal layer, in particular different from silver, with a thickness smaller than 10 nm, or better still smaller than 5 nm or even 3 nm.

The conductive strands may include a metal layer such as silver and be coated with a protective overlayer, in particular temporary, in particular polymeric.

The conductive strands may preferably be deposited directly on the first layer chosen to be partially structured, or even a dielectric sublayer, in particular for catching (with a catching function to facilitate the deposition of the grid material). The sub-layer is directly on the cavities (the bottom and preferably all or part of the flanks of the cavities) of the partially structured layer and preferably is absent from the surface of the partially structured layer, the catching layer preferably being mineral, in particular oxide(s), for example a conductive transparent oxide. The dielectric sublayer has a thickness e_{A} of less than 30 nm, even 10 nm. This catching layer is easily deposited by magnetron cathode sputtering.

For simplicity, it is preferable for the conductive strands to be directly in contact with a structured layer (no layer between the grid and the cavity bottom).

A is chosen to be less than or equal to 50 μm to limit the visibility to the naked eye of the strands, and e₂ is at least 100 nm to achieve the objective of a low Rsquare more easily.

The metal strands can be interconnected in the active zone of the OLED or connected (only) via their other ends to electric contacts.

The conductive strands may be in the form of linear strands parallel to one another and connected (to one another) to electric contacts at their ends and/or in the form of closed patterns or links (interconnected strands defining closed patterns), for example geometric (rectangle, square, polygonal, honeycomb, etc.) and with an irregular shape and/or irregular size. The conductive strands may have a zone with lines (strands or tracks in strips) and a zone with closed patterns (strands or tracks with links).

The thickness e₂ is not necessarily constant in a cavity along the width of the strand. Preferably, it is defined at the center of the surface of the strand. The width A is not necessarily constant in a given cavity. B may be defined as the maximum distance between the strands, in particular corresponding to a maximum distance between two points of a link or the average distance between two adjacent separate strands of the furrow type (which may or may not be straight).

A and B can vary from one strand to another. Because the conductive strands can be in the form of a grid, the grid can be irregular, the dimension A is therefore preferably the average dimension of the strands, like e₂ is also an average.

The thickness e₂ (defined at the center of the surface of the strand) may be less than 1500 nm, better less than 1000 nm, in particular in a range from 100 nm to 1000 nm, or less than 800 nm, and in particular in a range from 200 nm to 800 nm, in particular from 100 nm to 500 nm or even 100 nm to 300 nm if the structured layer is sol gel (structured overlayer alone, for example, or first partially structured layer).

The width A is preferably less than 30 μm to further limit the visibility of the strands to the naked eye. A is preferably in the range from 1 μm to 20 μm, still more preferably from 1.5 μm to 20 μm, or even from 3 μm to 15 μm. B is at least 50 μm, and even at least 200 μm, and B is less than 5000 μm, better less than 2000 μm, even less than 1000 μm.

Another feature of the conductive strands according to an embodiment of the invention is a coverage rate T that is preferably less than 25%, and better still less than 10%, and even less than 6% or 2%. Additionally, the insulating grid preferably has a coverage rate T′ less than or equal to T, less than 25% or less than 10%, and even less than 6%.

In particular, one may wish to have a B between 2000 μm and 5000 μm when e₂ is less than 500 nm and A is between 3 μm and 20 μm or 3 μm to 10 μm. This corresponds to a coverage rate between 0.5% and 22% or 0.5% and 11%.

For a given Rsquare, a large thickness e₂ of conductive strands will be favored with a high width A of strands to gain transparency.

In particular, several embodiments are possible regarding the anchoring of the conductive strands in the non-electroconductive domains.

In a first embodiment, the first layer, which is preferably electrically insulating, and even preferably a sol gel, is completely structured in terms of thickness with through holes with a width Wc, and preferably any barrier sub-player is not structured.

In a second embodiment, the first layer, which is preferably electrically conductive, and even preferably a sol gel, is partially structured in terms of thickness, and electrically insulating, while being made up of:

a region, called lower region, below the conductive strands,

a structured region, that region forming the non-electroconductive domains and with cavities—therefore blind holes—with width Wc, and preferably the side zones are adjacent to the first layer and have a width L1, L1 being greater than the height e_{c} of the cavities and L1≦2e_{c} and L1≦1.4e_{c}.

In a third embodiment,

the overlayer (single or multilayer), made from an electrically insulating material, preferably mineral, that is discontinuous defining through holes, the overlayer being part of the non-electroconductive domains, the top surface being the surface of the over-layer, with a thickness e_{z} of no more than 500 nm and even 300 nm, or no more than 100 nm, and preferably at least 20 nm,

the first layer, which is electrically insulating, preferably mineral, which is:

entirely structured (3) in terms of thickness, with through holes with a width Wc at the interface between the overlayer and the first layer—cavities receiving at least the lower part (of the central zone) of the conductive strands, the upper part of the central zone of the conductive strands extending optionally in the through holes of the overlayer, or even beyond the top surface)

or partially structured in terms of thickness, being made up of

a region, called lower region, below the conductive strands,

a structured region, below the overlayer (and on the lower region), region with cavities (therefore blind openings) with a width Wc across from the through holes, in particular cavities receiving at least the lower part (of the central zone) of the conductive strands (the upper part of the central zone of the conductive strands optionally extending in the through holes of the overlayer, or even past the upper surface).

At the interface between the overlayer and the first layer (overlayer—structured regions interface), the through holes having a width W1, the cavities having width Wc, preferably with Wc≧1, even Wc>W1.

When Wc>W1, strand zones, called edge zones, are adjacent to the side zones, are more peripheral than the side zones, and are in the cavities of the overlayer—thus flush with the first surface of the first layer (the side zones forming a recess of the edge zones with thickness e_{z}).

When Wc>W1, the side zones have a width L1 defined as the distance between points X″ and Y′, the edge zones with width L2 defined as the distance between points X′ and Y, Y″ is the orthogonal projection of Y in the plane of the surface of the side zones, L3 is the distance between X″ and Y″, L3 being greater than the total height e_{c}+e′_{c} and L3≦2(e_{c}+e′_{c}) and even L3≦1.4(e_{c}+e′_{c}), where e_{c} is the height of the cavities (taken in the middle) and e′_{c} is the height of the holes.

Preferably, A is defined at the top surface if W1>Wc and at the surface of the first layer if W1≦Wc. Preferably, B is defined at the top surface if W1>Wc and at the surface of the first layer if W1≦Wc.

When the first layer is partially structured in terms of thickness and the cavities, with height e_{c} preferably greater than 200 nm, are preferably delimited by flared flanks, the cavities widen moving away from the plastic substrate. A horizontal distance L may be defined greater than e_{c} and with L≦2e_{c}. L is between points X and Y, such that X is the highest point of the flank and Y is the point at the end of the bottom of the cavity.

The holes of the overlayer, with height e′_{c}, can be delimited by flared flanks, widening moving away from the plastic substrate, with a horizontal distance L′ greater than e′_{c} and with L′≦2e′_{c}.

When the first layer is a layer partially structured in terms of the thickness whereof the upper surface optionally forms the top surface, the deeper the cavities are, the larger the side zones are.

The overlayer is transparent with the lowest possible absorption.

Preferably, the overlayer is minimal, in particular comprises a layer of a metal and/or silicon oxide, a metal and/or silicon nitride, a metal and/or silicon oxide nitride (SiON). Its thickness e_{z} may be less than 200 nm, 150 nm, 100 nm, and even 5 or 20 nm to 80 nm. It may be a single layer or a multilayer, in particular of metal oxides or of metal oxides and metal nitrides (such as SiO₂/Si₃N₄).

The overlayer is for example a barrier (protection) layer or an acid etching stopper layer, for example aqua regia, which is the usual ITO etching solution used for the electroconductive coating. Preferably, the overlayer comprises at least one layer of a Ti, Zr, Al oxide and mixtures thereof, or Sn, and optionally containing silicon.

These oxides may be deposited by vapor deposition, in particular magnetron sputtering, or by sol gel. Preferably, the overlayer has a refractive index greater than 1.7. In case of multilayer, an average reflection index is defined preferably greater than 1.7. In the case of a multilayer, it is preferable for any layer with a refractive index below 1.7 to have a thickness of less than 50 nm.

The overlayer has blind holes, preferably through holes.

The holes may have a height e′_{c} greater than 20 nm, and preferably at least 50 nm or 100 mm, and preferably less than 300 nm, and a width A′_{c} less than or equal to 30 μm. e′_{c} is taken at the center of the hole.

The holes may form furrow (one-dimensional), which may or may not be regularly spaced apart, in particular separate (at least one in the light-emitting zone) of any shape, for example straight or sinuous.

The holes may form a mesh, i.e., a network of interconnected openings (two-dimensional), periodic or aperiodic, with regular or irregular links, of any shape: in particular geometric (square, rectangle, honeycomb). The links may be defined by a maximum length between two points of a link.

The cavities in the first layer (formed in a grid, defining the arrangement of the conductive strands) are preferably filled by the conductive strands. The cavities are delimited by a bottom and flanks most often forming a basin. The cavities may extend partly or completely through the thickness of the first layer.

The cavities in of the first layer separating the non-electroconductive domains may have a height e_{c} greater than 200 nm, and even at least 250 nm or 500 nm, and preferably less than 1500 nm or 1200 nm and a width A_{c} of less than or equal to 30 μm. e_{c} is taken at the center of the cavity. A_{c} is preferably taken at the bottom of the cavity.

The cavities in the first layer can form furrows (one-dimensional), which may or may not be regularly spaced apart, in particular separate (at least in the light-emitting zone) of any shape, for example straight or sinuous.

The cavities in of the first layer may form a mesh, i.e., a network of interconnected openings (two-dimensional), periodic or aperiodic, with regular or irregular links, of any shape: in particular geometric (square, rectangle, honeycomb). The links may be defined by a maximum length between two points of a link.

Preferably, e_{c} is greater than 200 nm, even greater than 250 nm or 500 nm. e_{c} is preferably submicronic. Preferably, e′_{c} is greater than 100 nm, even greater than 250 nm and less than or equal to 500 nm. e′_{c} is preferably submicronic.

The electroconductive support according to an embodiment of the invention can be used for a bottom emission light-emitting device or for an organic bottom and front emission light-emitting device. In another embodiment, the electroconductive support can be used in another electrochromic device, such as a liquid crystal display.

The electroconductive coating has a resistivity ρ₅ of less than 20 Ω·cm, even 10 Ω·cm or 1 Ω·cm, and even 10⁻¹ Ω·cm, and greater than the resistivity of the conductive strands, and has a given refractive index n₅ of at least 1.55, but are still 1.6, and even better 1.7.

It is preferable to adjust the resistivity as a function of the distance between the strands. It is lower when B is higher.

For example, for B=1000 μm, and e₅=100 nm, a resistivity of less than 0.1 Ω·cm is preferred. For B is 200 μm and e₅=100 nm, a resistivity of less than 1 Ω·cm is preferred.

The electroconductive coating according to an embodiment of the invention contributes to a better distribution of the current.

The surface of the electroconductive coating may preferably be designed to be in contact with the organic layers of the OLED: in particular, the HIL or the HTL, or may be part of the HIL or HTL or act as HTL or HIL.

The (outer) surface of the electroconductive coating may further have very large-scale undulations, typically greater than 0.1 mm. Furthermore, the substrate may be curved.

The electroconductive coating is preferably a single layer rather than multilayer.

The surface of the coating may reproduce the surface roughness of the grid, in particular obtained by vapor deposition. The coating above the central zone may be under-flush with the top surface.

The coating may have an adaptation layer for the output work, which may for example have an output work Ws from 4.5 eV, and preferably greater than or equal to 5 eV.

The electroconductive coating may thus comprise (or preferably is made up of) a mineral layer with a refractive index nₐ between 1.7 and 2.3, preferably which is the last layer of the coating (furthest from the substrate) and even the only one, in particular for adaptation of the output work, preferably with a thickness of less than 150 nm, with an electroconductive transparent oxide, simple or mixed oxide base:

in particular with a base of the least one of the following metal oxides, optionally doped: tin oxide, indium oxide, zinc oxide, molybdenum oxide MoO₃, tungsten oxide WO₃, vanadium oxide V₂O₅,

ITO (preferably), a layer (in particular amorphous), for example with a base of zinc and tin oxide SnZnO, or a base of indium and zinc oxide (called IZO), or a base of indium, zinc and tin oxide (called ITZO).

Preferably, a layer with a base of zinc oxide is doped with aluminum and/or gallium (AZO or GZO).

A layer of a ZnO oxide is preferably doped with Al (AZO) and/or Ga (GZO) with the sum of the percentages by weight of Zn+Al or Zn+Ga or Zn+Ga+Al or Zn+another doping agent probably chosen from among B, Sc or Sb or from among Y, F, V, Si, Ge, Ti, Zr, Hf and even In, which is at least 90% in total weight of metal, better still at least 95%, and even at least 97%.

It may be preferred, for a layer of AZO according to an embodiment of the invention, for the percentage by weight of aluminum over the sum of the percentages by weight of aluminum and zinc, in other words Al/(Al+Zn), to be less than 10%, preferably less than or equal to 5%.

To that end, it is preferably possible to use a ceramic target of aluminum oxide and zinc oxide such that the percentage by weight of aluminum oxide over the sum of the percentages by weight of zinc oxide and aluminum oxide, typically Al₂O₃/(Al₂O₃+ZnO), is less than or equal to 14%, preferably less than or equal to 7%.

It may be preferred, for a layer of GZO according to an embodiment of the invention, for the weight percentage of gallium over the sum of the weight percentages of zinc and gallium, in other words Ga/(Ga+Zn), to be less than 10%, and preferably less than or equal to 5%.

To that end, it is preferably possible to use a ceramic target of zinc oxide and gallium oxide such that the percentage by weight of gallium oxide over the sum of the percentages by weight of zinc oxide and gallium oxide, typically Ga₂O₃/(Ga₂O₃+ZnO), is less than 11%, preferably less than or equal to 5%.

In a layer with a base of tin and zinc oxide (SnZnO), the total percentage by weight of Sn metals preferably goes from 20 to 90% (and preferably from 80 to 10% for Zn), and in particular from 30 to 80% (and preferably from 70 to 20% for Zn), in particular the weight ratio of Sn/(Sn+Zn) preferably goes from 20 to 90%, and in particular from 30 to 80%.

The mineral layer, preferably ITO or with a base of zinc oxide, preferably has a thickness of less than or equal to 60 nm, 50 nm or even 40 nm or 30 nm, and even 10 nm, and has a resistivity of less than 10⁻¹ Ω·cm. Preferably, a layer is chosen that is deposited by physical vapor deposition, in particular by magnetron sputtering, chosen from among ITO and ZnO (AZO, GZO, AGZO), or MoO₃, WO₃, V₂O₅.

Indium tin oxide (or indium oxide doped with tin, or ITO) preferably refers to a mixed oxide or mixture obtained from oxides of indium (III) (In₂O₃) and tin oxide (IV) (SnO₂), preferably in weight proportions between 70% and 95% for the first oxide and 5% to 20% for the second oxide. A typical weight proportion is approximately 90% by weight of In₂O₃ for approximately 10% by weight of SnO₂.

The electroconductive coating may be made up of the mineral layer with a refractive index nₐ between 1.7 and 2.3, then equal to n₅.

The electroconductive coating may comprise or be made up of, at least on the last layer (of the coating) furthest from the substrate, an organic layer of electroconductive polymer(s), with a submicronic thickness e′₅, with a refractive index n_{b} of at least 1.55, better still 1.6, the polymeric layer being able to act as a hole transport layer (HTL) or a hole injection layer (HIL) of an organic light-emitting system.

The electroconductive coating may be made up of the organic layer with a refractive index n_{b} between 1.7 and 2.3, then equal to n₅.

For example, it involves a layer of one or more (electro)conductive polymers from the family of polythiophenes, such as PEDOT or PEDOT:PSS, i.e., PEDOT mixed with polystyrene sulfonate.

Examples of commercial PEDOT or PEDOT:PSS include, from the company Heraeus:

Clevios™ F AND with ρ of less than 10⁻² Ohm·cm,

or Clevios™ HIL 1.1 with ρ of approximately 10.

The electroconductive coating may be multilayer and comprises (preferably directly), below the aforementioned mineral layer (in particular last layer), a first layer directly on the conductive strands (single layer or multilayer grid), made from the conductive transparent oxide, with a thickness e′5 of less than 200 nm, with index n′5 between 1.7 and 2.3, the deviation in absolute value n′5-n₃ preferably being less than 0.1, in particular chosen from among:

preferably, a layer with a base of zinc oxide, in particular doped with aluminum and/or gallium (AZO or GZO), or optionally with ITZO, and/or

a layer (in particular amorphous), for example with a base of zinc and tin oxide SnZnO, preferably with a thickness of less than 100 nm, or with a base of indium and zinc oxide (called IZO), or with a base of indium, zinc and tin oxide (called ITZO).

The layer of AZO or GZO may for example make it possible to reduce the thickness of the metal layer, in particular the layer of ITO, to less than 50 nm.

In particular, it is possible to have the ITO/A(G)ZO or GZO bi-layer, or the (A)GZO or AZO/ITO bi-layer.

The electroconductive coating is preferably a layer (preferably single layer) like those already mentioned or is a composite layer including, in a (weakly) electroconductive polymeric matrix, metal nanowires, in particular silver.

The electroconductive support may also include a temporary (removable) protection layer that is for example mineral, for example oxide or nitride, or polymeric, for its transport to the deposition location of the electroconductive coating, separate from the deposition location of the grid.

The substrate can be planar or curved, and may further be rigid, flexible or semi-flexible.

Its main faces may be rectangular, square or even any other shape (round, oval, polygonal, etc.). This substrate may be large, for example with a surface greater than 0.2 m² or even 0.5 m² or 1 m², and with a lower electrode substantially occupying the surface (to within the structuring zones).

The substrate made from plastic material may be substantially transparent, from polycarbonate (PC) or PMMA or polyethylene terephthalate (PET), polyvinyl butyral (PVB), polyurethane (PU), polytetrafluoroethylene (PTFE), etc.

Advantageously, a thermoplastic polymer is chosen with a high refractive index, such as PEN.

The thickness of the substrate may be at least 0.1 mm, preferably in a range from 0.1 mm to 6 mm, in particular from 0.3 mm to 3 mm.

The support as previously defined may further include an organic light-emitting system deposited (preferably directly) on the electroconductive coating and the passivation layer optionally including an HTL or HIL.

OLED-Device General Information

An embodiment of the invention can be an organic light-emitting device incorporating the support as previously described, the electrode with the conductive strands forming the lower electrode, closest to the first surface, generally the anode, in particular covered by a light-emitting layer of organic light-emitting material(s), the light-emitting layer being covered by the upper electrode, generally the cathode.

For the upper electrode, it is possible to use a metal layer (reflective, or even semi-reflective, etc.), for example made from Ag, Al, Pd, Cu, Pd, Pt, In, Mo, Au.

The OLED device may produce monochromatic light, in particular blue and/or green and/or red, or may be adapted to produce white light.

To produce white light, several methods are possible: mixing components (red green, blue emission) in a single layer, stacking on the face of the electrodes of three organic structures (red green, blue emission) or two organic structures (yellow and blue), series of three adjacent organic structures (red green, blue emission), on the face of the electrodes an organic structure in one color and on the other face, appropriate luminophore layers.

The OLED device may comprise a plurality of adjacent organic light-emitting systems, each emitting white light or, per series of holes, red, green and blue light, the systems for example being connected in series.

Each row may for example emit according to a given color.

The OLEDs are generally separated into two major families depending on the organic material used. If the light-emitting layers are small molecules, they are called SM-OLED (Small Molecule Organic Light-Emitting Diodes). The organic light-emitting material of the thin layer is made from evaporated molecules such as the complex of AlQ₃ (tris(8-hydroxyquinoline) aluminum), DPVBi (4,4′-(diphenyl vinylene biphenyl)), DMQA (dimethyl quinacridone) or DCM (4-(dicyanomethylene)-2-methyl-6-(4-dimentylaminostyryl)-4H-pyran). The emissive layer may also for example be a layer of 4,4′,4″-tri(N-carbazolyl) triphenylamine (TCTA) doped with fac-Tris(2-phenylpyridine) iridium [Ir(ppy)₃].

In general, the structure of an SM-OLED includes a stack of HILs, HTLs, emissive layer, electron transport layer (ETL).

Examples of organic light-emitting stacks are for example described in document U.S. Pat. No. 6,645,645, which is incorporated herein by reference in its entirety.

If the organic light-emitting layers are polymers, they are called PLED (Polymer Light-Emitting Diodes).

Preferably, the electroconductive coating is resistant to the following steps for manufacturing the OLED:

keeping at 150° C. for 1 h,

keeping at a pH of 13 (cleaning solution),

keeping at a pH between 1.5 and 2 (in particular if deposition for the electroconductive polymer coating, before deposition of the OLED system),

pulling out test (scotch test).

In particular when the plastic has a high index of more than 1.65, and even at least 1.7, it is not necessary to add a light extraction layer between the moisture barrier layer (or for the moisture barrier to be diffusing) and the first layer in the form of a diffusing layer, or to make the first face diffusing.

A means for extracting light may be situated on the outer face of the substrate, i.e., the face that will be opposite the first main face bearing the electrode grid. This may be a network of micro-lenses or micro-pyramids, in particular as described in the article in the Japanese Journal of Applied Physics, Vol. 46, no. 7A, pages 4125-4137 (2007).

An embodiment of the invention lastly relates to a method for manufacturing an electroconductive support as previously defined that includes the following steps, in the following order:

providing the substrate, including:

a potential sub-layer forming a moisture barrier on the first surface,

a high index continuous layer, made from the composition with a refractive index n₃ of the first layer,

the formation of cavities or through holes in the high index layer, thereby forming a first layer with a structured thickness whereof the surface is the top surface, that formation including:

producing, on the high index layer, a discontinuous masking layer made from a (negative or positive) photoresist with a given arrangement of through openings, with flanks, in particular for:

coating the photoresist,

exposure to the ultraviolet using an ultraviolet source on the side of the first surface.

wet etching of the high index layer through the through openings of the masking layer, creating zones of the masking layer suspended above the cavities or through holes and thus defining surface portions called inner surfaces of the masking layer across from the cavities or through holes, the width of the openings W1 being smaller than the width Wc of the cavities or through holes at the upper surface,

forming the conductive strands comprising a wet chemical deposition, preferably electroless, of a first metal material of the grid in the cavities or through holes, the first material being deposited on the flanks (of the first de limiting layer) of the cavities and completely on the inner surfaces of the masking layer, thereby forming the side strand zones flush with the top surface and less rough than the central zones of the strand,

removing the masking layer, in particular by wet chemical means,

preferably, depositing the electroconductive coating, preferably mineral, for example by physical vapor deposition,

optionally, forming the passivation layer in the form of insulating tracks above the central zones of the strands, said passivation layer preferably being on the electroconductive coating present on the central zones.

The etching is done using a wet etching method. The depth of the cavities is adjusted by the concentration of the solution, the type of solution, the duration of the etching and/or the temperature of the solution. The photosensitive masking layer is then resistant to the etching solution.

The etching with a wet solution is vertical and lateral inasmuch as the etching solution etches (hollows) in all directions. The etching profile may form a basin, of the semi-spherical type.

The cavities have flared flanks toward the direction opposite the substrate (widening moving away from the substrate). The section may be basin-shaped, even of the semi-spherical type.

The similar manufacturing method using a structured overlayer on the first layer, said overlayer already having been described and the surface of which forms the top layer, is described below.

An embodiment of the invention therefore also relates to a method for manufacturing an electroconductive support as previously defined (with an overlayer on the first layer) that includes the following steps, in the following order:

providing the substrate, comprising:

an optional moisture sub-barrier layer on the first surface,

a continuous high index layer, made from the composition with a refractive index n₃ of the first layer,

(directly) on the high index layer, an electrically insulating continuous layer called additional layer, made from the material of the overlayer,

forming blind or through openings in the additional layer, thereby forming the overlayer whereof the thickness is completely or partially structured, that formation including:

producing, on the additional layer, a masking layer made from a (negative or positive) photoresist with a given arrangement of through openings, and with flanks, in particular by

coating the photoresist,

exposure to ultraviolet using an ultraviolet source on the side of the first surface,

wet etching of the additional layer, with the first etching solution, through the through openings of the masking layer, creating zones of the masking layer suspended above blind or through holes and thus defining surface portions, called inner surfaces, of the masking layer across from the blind or through holes,

forming cavities or through holes in the high index layer, thereby forming the first partially structured layer with Wc>W1, that formation including:

wet etching of the high index layer, with a second etching solution, preferably different from the first solution and preferably not etching the overlayer, through the through openings of the masking layer, through holes of the overlayer, creating zones of the masking layer and the overlayer suspended above the cavities in the first layer and thereby defining surface portions called other inner surfaces of the overlayer across from the cavities in the first layer,

forming the conductive strands comprising a wet chemical deposition, preferably electroless, of a first metal material of the conductive strands in the through cavities in the first layer and in the through holes of the overlayer, thereby forming the side strand zones flush with the top surface below the inner surfaces while being less rough than the central zones of the strand, the first material being deposited on the flanks of the through holes of the overlayer, completely on the other inner surfaces of the overlayer, on the inner surfaces of the masking layer, thereby forming the edge zones and side strand zones,

removing the masking layer (60), in particular by wet chemical means,

preferably, depositing the electroconductive coating, preferably mineral, for example by physical vapor deposition,

preferably, forming the passivation layer in the form of insulating tracks above the central zones of the strands, preferably on the electroconductive coating present on the central zones.

The depth of the cavities (and/or holes of the overlayer) is adjusted by the concentration of the solution, the etching duration and/or the temperature of the solution. The photosensitive masking layer is resistant to the etching solution (to the first and second etching solutions). The cavities (and/or the holes of the overlayer) are flared in the direction opposite the substrate (widening moving away from the substrate).

The etching with a wet solution is vertical and lateral in that the etching solution etches (hollows) in all directions. The etching profile can be basin-shaped, of the semi-spherical type. This etching in all directions is the source of the zones of the masking layer suspended above the cavities or the blind or through holes.

Wc>W1 is preferred because it is thus easier to create peripheral side zones flush with the top surface that are smooth.

It is preferred for the electroconductive coating to be mineral because the latter better resists the aqueous chemical solutions used during chemical development steps of the layer of photoresist and/or elimination of part of the layer of photoresist.

Advantageously, the method comprises forming the passivation layer in the form of insulating tracks on the central zones of the strands and includes:

coating the positive photoresist of the passivation layer covering the electroconductive coating,

the exposure to the ultraviolet using an ultraviolet source on the side of the second main face,

development in solution until the layer of positive photoresist is made discontinuous, the positive photoresist remaining localized above the conductive strands to form the passivation layer.

The passivation method includes a photolithography step, but without using a photolithography mask or an alignment step, which would create an excess cost and complexity. During the UV exposure on the side of the second face, each (opaque) metal strand forms a screen to the UV, such that the positive photoresist above the strand is not exposed and is insoluble in the developer. The passivation layer is therefore self-aligned on the conductive strands. Based on the development, the flanks will be more or less oblique, generally such that the width of the insulating strand decreases with the thickness.

The width of the passivation layer can be controlled, via the irradiating conditions and development conditions of the layer of positive photoresist, so as to be larger than that of the central zones of the strands, so as to make the elimination of the leakage current more effective, while doing away with edge effects.

The thickness of the passivation may be controlled via the concentration of the solution of photosensitive passivation material, also as well as the irradiating conditions and/or the development conditions (time and concentration).

The formation of the passivation layer is particularly quick and easy because there is no need for a step for depositing another sacrificial material that must subsequently be completely removed. In particular, when H is no more than 100 nm, the removal of the masking layer (before the deposition of the electroconductive coating) creates metal protuberances with a height of at least 10 nm running along the inner edges of the side zones of the conductive strands, and the method comprises, after the removal of the masking layer and before the deposition of the electroconductive layer, a step for wet etching to eliminate the protuberances.

The wet chemical deposition of the first metal material is preferably a silvering, and preferably the grid is a single layer.

Advantageously, the wet chemical deposition (preferably only deposition for the metal grid) can be silvering, and preferably the grid is a single layer, and even the first material (which has a base of silver) is deposited directly in the bottom of the cavities or blind holes.

The solution for the silvering step may contain a silver salt, a silver ion reducer and even a chelating agent. The silvering step may be carried out according to traditional operating most commonly used in the field of manufacturing mirrors, and for example described in Chapter 17 of the work “Electroless Plating—Fundamentals and Applications”, published by Mallory, Glenn O.; Hajdu, Juan B. (1990) William Andrew Publishing/Noyes.

In one preferred embodiment, the filtering step comprises (by submersion in a bath or spraying with a solution) placing the substrate having the possible sublayer, the first layer, the possible overlayer and the masking layer with through openings in contact with a mixture of two aqueous solutions, one containing the metal salt, for example silver nitrate, and the other containing the metal ion reducing agent (Ag⁺ ions), for example sodium, potassium, aldehydes, alcohols, sugars.

The most commonly used reducing agents are Rochelle salt (double potassium sodium tartrate KNaC₄H₄O₆, 4H₂O), glucose, sodium gluconate and formaldehyde.

Preferably, before this placement in contact, the silvering step comprises a sensitization step (of the surface of the cavities and/or the holes of the overlayer) preferably comprising a treatment using a tin salt and/or an activation step (of the surface of the cavities and/or holes of the overlayer) preferably comprising treatment with a palladium salt. These treatments essentially serve to favor metallization (by the silver) at a later time and to increase the appearance of the formed silver metal layer (in the cavities and/or the overlayer or holes). For a detailed description of these sensitization and activation steps, reference may for example be made to US 2001/0033935.

More specifically, it is possible to perform the silvering by submerging the substrate having the possible sublayer, the first layer, the possible overlayer and the masking layer with through openings, in a photoresist, in tubs, each with one of the following three solutions, in the following order:

a first aqueous solution of SnCl₂ (sensitization), preferably with agitation (preferably for less than 5 minutes, for example 0.5 to 3 minutes), then rinsing with (distilled) water,

a second aqueous solution of PdCl₂ (activation), preferably with agitation (preferably for less than 5 minutes, for example 0.5 to 3 minutes), then rinsing with (distilled) water,

a third, which is a mixture of the silver salt solution, preferably silver nitrate, and the reducing solution for the silver, preferably sodium gluconate, preferably with agitation (preferably for less than 15 minutes and even 5 minutes, for example 0.5 to 3 minutes), then rinsing with (distilled) water.

The substrate, coated and thus silvered, is next removed from the last bath and rinsed with (distilled) water.

Another embodiment includes spraying the three previous solutions in the same order as above, rather than submerging the substrate having the possible sublayer, the first layer, the possible overlayer and the masking, layer with through openings in photoresist.

The removal of the masking layer (before the deposition of the electroconductive coating) is preferably done via a wet chemical method, in particular by ultrasound in a solvent (e.g., acetone, etc.).

The high index layer may be polymeric.

The deposition of the electroconductive layer, direction on the grid and (directly) on the first layer or any overlayer, single layer or multilayer coating and/or single or multi-material coating, may be by physical vapor deposition, in particular by cathode sputtering, with a possible first deposition of SnZnO or AZO, and a second or last—and preferably single—deposition of ITO or with a base of ZnO (doped), or MoO₃, WO₃ or V₂O₅.

The method may comprise, before depositing the electroconductive coating, a heating step, to a temperature below 200° C., preferably between 150° C. and 180° C., for a duration preferably between 5 minutes and 120 minutes, and in particular between 15 and 90 minutes and/or a heating step after the deposition of the electroconductive coating, preferably mineral, before or after the deposition of the passivation layer, at a temperature below 200° C., preferably between 150° C. and 180° C., for a duration preferably between 5 minutes and 120 minutes, in particular between 15 and 90 minutes.

This annealing may serve to improve the quality of the silver, decrease the absorption of the electroconductive coating such as ITO (if it involves a first annealing) and the durability of the passivation layer.

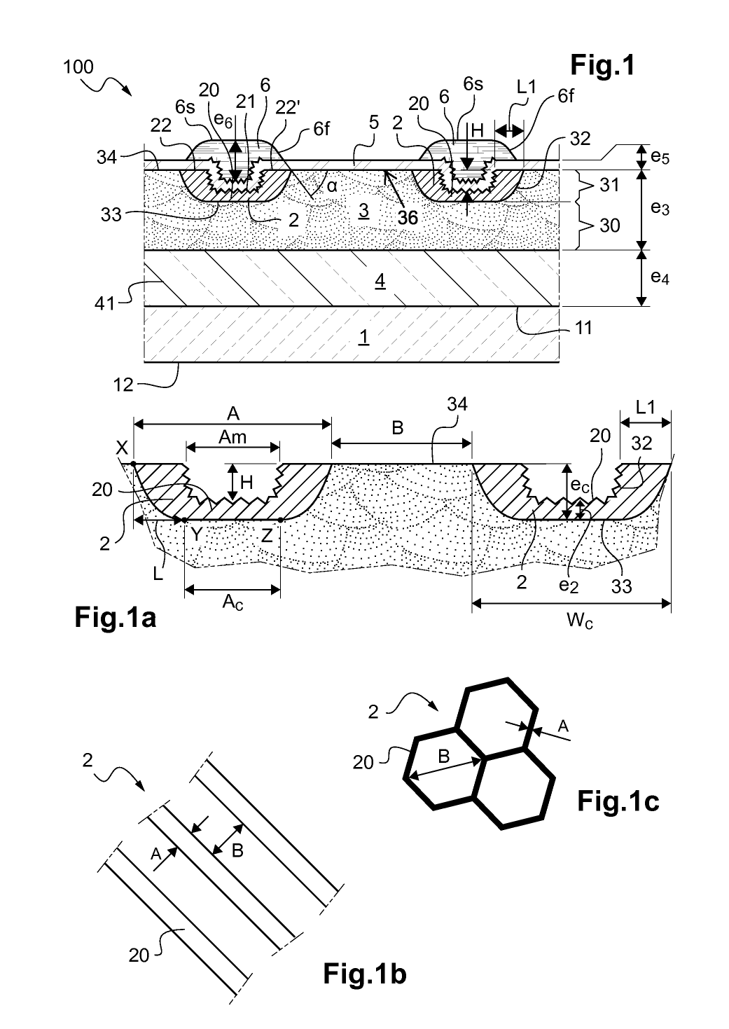

FIG. 1, diagrammatic, shows lateral sectional view of the electroconductive support 100 for an organic light-emitting device OLED with bottom emission.

This support 100 includes a plastic substrate with a refractive index nₛ of 1.45 to 1.8, smooth with a first main face 11, called first surface, bearing, in the following order moving away from the substrate:

a moisture barrier layer 4 such as silicon nitride 41 or a stack of thin layers,

a first layer 3 with a partially structured thickness, polymeric or preferably mineral, with a high index, with a refractive index n₃ of 1.7 to 2.3, preferably from 1.80 to 2.10, and in particular from 1.85 to 2.00, preferably an electrically insulating material, with a thickness e₃ that is preferably micronic or submicronic and has a primary surface 36, including:

a (continuous) region, called lower region 30, which here is directly on the sublayer, with a given thickness e′₃ (preferably micronic), covering the surface of the sublayer,

a structured region 31, raised and hollow, the raised portions defining a flat top surface 34, the cavities or hollows being delimited by a bottom 33 (defining a lower surface) and flanks 32, cavity with width Wc at the top surface 34 and height e_{c} at the middle, preferably at most 1500 nm and preferably greater than 100 nm, the cavities extending in a given arrangement (separate strips, mesh, etc.) that may be regular or irregular, the top surface being locally planar,

an electrode 2, including a layer arranged in a grid 2, called metal grid, made from metal material(s) obtained by electroless deposition, preferably single layer of silver (obtained by silvering), the grid here being a single layer formed by strands—otherwise called tracks—20 anchored in the cavities, the strands having a width A smaller than 50 μm at the top surface 34, better smaller than or equal to 30 μm (and at least 1 μm), and being spaced apart at the top surface 34 by a distance B smaller than or equal to 5000 μm and at least 50 μm, the grid having a thickness e₂ defined at the middle of the strand of at least 100 nm and preferably less than 1500 nm, the metal grid having a sheet resistance of less than 20Ω/□, and even less than 10Ω/□, or 5 Ω/□,

an electroconductive coating 5, preferably in a single layer and even mineral, with a thickness e₅ of less than or equal to 500 nm or 100 nm, and even less than or equal to 60 nm, with a resistivity ρ₅ of less than 20 Ω·cm and greater than the resistivity of the metal grid, and has a given refractive index n₅ of at least 1.5, and better still 1.7, here made up of a mineral layer that is preferably made from ITO (or AZO or GZO, AGZO) on the grid 2 and the top surface 34, or alternatively which is a high index conductive polymeric layer such as PEDOT:PSS deposited by wet chemical means, with a resistivity ρ₁ for example of approximately 10⁻¹ Ohm·cm, with a thickness of approximately 100 nm or more,

a passivation layer 6 directly on the electroconductive coating 5, discontinuous in photoresist, with a thickness e₆ (taken at the middle of the cavity) of less than 1000 nm.

The cavities have flared flanks due to the wet etching method of a continuous layer during the formation of the first partially structured layer outlined below.

The strands 20 have, along their length, a central zone 21 between side zones 22, 22′ that are flush with the top surface 34, and the surface roughness of the central zone 21 is greater than the surface roughness of the side zones 22, 22′.

In order to characterize the metal grid 2, as shown in FIG. 1a (detailed view of FIG. 1 without the passivation layer), we have shown A, B, e₂, as well as the width of the central zone Aₘ, and for the cavities, the width A_{c} at the bottom of the cavity, and e_{c} is the height starting from the center of the bottom of the cavity.

The flanks are flared (widening moving away from the substrate 1), and a horizontal distance L is defined between X and Y such that X is the highest point of the flank and Y is the point at the end of the bottom of the cavity. L Is greater than e_{c}, L≦2e_{c}, and even L≦1.4e_{c}.

In the central zone 21, the middle of the strand surface and the top surface are separated by a vertical distance H taken at the normal to the first surface and which is less than or equal to 500 nm. Here, the central zone 21 is under-flush with the top zone 34.

The strands have a central zone 21 that is rougher than the side zones due to the electroless deposition, such as silvering, and smooth side zones 22, 22′ with width L1. The width of the central zone Aₘ is not necessarily greater than L1; this depends on the values of A, H and e_{c}.

Examples of roughness parameters of the central zones and planar side zones are recorded in the following table as a function of the thickness e₂.

| Strand surface | e₂ (nm) | Rq (nm) | Rmax (nm) |
|---|---|---|---|
| Side zones | 300 | 2 | 10 |
| Central zone | 300 | 30 | 300 |
| Side zones | 200 | 1.5 | 8 |
| Central zone | 200 | 20 | 200 |
| Side zones | 450 | 2 | 10 |
| Central zone | 450 | 35 | 450 |

The ITO coating 5 is preferably deposited by magnetron cathode sputtering. Its surface then conforms to the underlying surface: surface of the first partially structured layer 3, with planar and smooth side zones 22, 22′, with central zones 21 rougher than the side zones.

The passivation layer 6 forms a grid of insulating tracks located above the central zones 21 and above the side zones 22, 22′ of the strands, covering the central zones and partially or completely covering the side zones and not protruding laterally past the outer edges of the strands or protruding laterally past the outer edges of the strands by at most 1 μm. Here, the flanks 6f of each insulating track are oblique with an angle α with the top surface 34 of approximately 45°. The section of each insulating track is dome-shaped, with no sharp angles. The upper surface 6s of each insulating track and the flanks 6f of each insulating track being smooth, the passivation layer 6 planarizes the central zone 21 and retains the smooth nature of the side zones 22, 22′.

In order to next manufacture an OLED device, an organic light-emitting system, single or multi junction (tandem, etc.), is added to a reflective (or semi-reflective) upper electrode, in particular metal, for example with a base of silver or aluminum.

FIG. 1b illustrates a diagrammatic top view of the metal grid, for example used in the support 100 of FIG. 1. It is a metal grid with linear, separated strands 20 (therefore in cavities forming linear, separated furrows) with width A at the top surface and distance B at the top surface, for example used in the support 100 of FIG. 1. The distance between patterns B corresponds to the average distance between adjacent strands.

FIG. 1c shows a diagrammatic top view of the metal grid, for example used in the support 100 of FIG. 1. The metal grid 2 is in the form of interconnected strands 20 forming links or closed patterns for example in a honeycomb or any other geometric (square, etc.) or non-geometric shape. The distance between patterns B corresponds to the maximum distance between two points of a link.

In example no. 1 relative to the first embodiment (of FIG. 1), the following features have been chosen.

The plastic 1 is planar, smooth, made from PEN, with an index of approximately 1.75, for example 150 μm thick, and a T_{L} of at least 90%.

The barrier layer is a stack of thin layers of metal or silicon oxides or nitrides.

The first layer is a TiOₓ sol gel layer with a thickness of 400 nm. This layer may alternatively be deposited by cathode sputtering.

The thickness e_{c} is 350 nm. The cavities of the first layer 3 are obtained by etching, as outlined later.

The first partially structured layer 3 is locally planar. The roughness of the top surface 34 is defined by an Rq of less than 4 nm.

The grid 2 is a single layer of silver deposited directly in the cavities by silvering, as outlined later. The silver here partially fills the cavities, with e₂ equal to approximately 300 nm. H is therefore equal to 50 nm. The pattern of the grid, which is a mesh, is hexagonal. The width A is equal to 12 μm, and the maximum distance B is 560 μm. The coverage rate T is 4.5%.

The electroconductive coating 5 is made up of a layer of indium tin oxide ITO of 50 nm with a refractive index of approximately 2, and a resistivity ρ₅ of less than 10⁻¹ Ω·cm.

The Rsquare of the assembly (after annealing at 150° C. for 30 minutes), measured using the traditional 4 point method, is approximately 3.0 Ohm/square.

The passivation layer forming the localized insulating grid is in turn a layer of positive photosensitive polyimide with e₆ being approximately 300 nm.

Next, a light-emitting system is added that may include:

an HTL with a variable thickness (between approximately 200 nm and 600 nm)

an electron blocking layer (EBL) of 10 nm

an orange emitting layer of 10 nm

a blue emitting layer of 25 nm

a hole blocking layer (HBL) of 10 nm

an electron transport layer (ETL) of 40 nm.

The cathode is a layer of aluminum measuring 100 nm.

FIGS. 7a to 7i are diagrammatic views (not to scale) of the manufacture of an electroconductive support according to the first embodiment, in particular relative to example no. 1, with manufacturing of the first partially structured layer by chemical etching, and manufacturing of the silver grid by silvering.

The first step illustrated in FIG. 7a includes, from the PEN substrate 1 coated with the sub-layer, of:

forming, on the sublayer, a high index layer 3a, which includes the material of the first layer with said refractive index n₃,

applying, by spin coating, a layer 60 of a masking material in liquid state, a positive photoresist, AZ® 1505 resin, on the layer 3a.

The deposited photoresist is next annealed at 100° C. for 20 minutes in a convection oven. The thickness of the photoresist is 800 nm.

The second step illustrated in FIG. 7b includes generating the photoresist pattern. To that end, a photolithography mask 70 with discontinuities 71 is applied on the resin 60 and the resin 60 is subjected to UV radiation on the side of the main first face 11 with a Hg lamp, at 20 mW/cm² (at 365 nm), for 10 seconds through the discontinuities 71, in an irregular or regular arrangement, in separated (parallel) strips or interconnected strips for a mesh.

The third step illustrated in FIG. 7c includes creating through openings in the photoresist 60. The radiated zones are eliminated by dissolution in a specific developer with a base of tetramethylammonium hydroxide (TMAH) and rinsed with deionized water, thus forming through openings through the photoresist. The flanks 61 of the photoresist delimiting the through openings are flared moving away from the PEN substrate. Thus, at the outer or upper surface 63 of the photoresist 60, the width of each through opening is greater than the width W0 at the top surface 34.

Alternatively, it is possible to use a negative photoresist and an inverse photo etching mask (removal of non-radiated zones to form the openings).

The fourth step illustrated in FIG. 7d includes creating cavities in the dielectric and high index continuous layer 3a, such as the layer of TiOx. It is preferred to form the first partially structured layer by wet etching rather than dry, at ambient temperature. The selected resist 60 is therefore resistant to the etching solution, which here is a solution with a base of NH₃ and H₂O₂. The etching forms cavities with a depth e_{c}, flanks 32, and the cavities are flared moving away from the plastic 1. For example no. 1, e_{c} is equal to 350 nm.

The etching solution etches (hollows) in all directions: vertically and laterally.

The etching profile is basin-shaped. The wet etching of the high index layer 3a creates zones of the masking layer suspended above the cavities and thereby defining surface portions, called inner surfaces 62, 62′, of the masking surface 60 across from the cavities 32. Each cavity has a width Wc (at the top surface) larger than the width W0. The inner surfaces 62,62′ have a width L0 substantially equal to L. The bottom 33 of the cavities is flat.

The fifth step illustrated in FIG. 7e includes depositing the grid material 2, via a wet chemical method and more specifically an electroless method, thus preferably by silvering. The deposition is done through openings of the photoresist 60 (resistant to etching), in the cavities to preferably partially fill them as illustrated here.

The silver is deposited, in the bottom of the cavities, on the flanks of the cavities, on the inner surfaces 62, 62′ of the photoresist, on the flanks of the photoresist (and is absent from the top surface of the layer 3) and on the discontinuous upper surface 63.

More specifically, the silvering partially fills each cavity and is deposited in the bottom, on the flanks and over the entire inner surfaces 62, 62′ of the masking layer, thereby forming side strand zones 22, 22′ flush with the top surface and less rough than the central strand zone 21 across from the through opening. The width L1 of each side zone 22, 22′ is approximately equal to L0+e2.

For example no. 1, the layer of silver is deposited in the first partially structured layer 3 using the following operating mode for a thickness e₂ of approximately 300 nm (with H equal to 50 nm and the central zone under-flush):

dilution of the silvering solutions (solutions for dilution provided by the company DR.-ING. SCHMITT, GMBH Dieselstr. 16, 64807 Dieburg/GERMANY) according to:

100 μL of Miraflex® 1200 (SnCl₂ solution) in a vial of 250 cm³ (sol no. 1)

200 μL of Miraflex® PD (PdCl₂ solution) in a vial of 250 cm³ (sol no. 2)

15 mL of Miraflex® RV (reducing solution, sodium gluconate) in a vial of 250 cm³ (sol no. 3)

15 mL of Miraflex® S (silver nitrate solution) in a vial of 250 cm³ (sol no. 4)

the aforementioned solutions are used at ambient temperature;

placing the substrate (with layers 4, 3) in a tub in which the contents of solution no. 1 are poured, agitation for 1 minute, then rinsing with distilled water;

placement of the substrate (with layers 4, 3) in a second tub in which the contents of solution no. 2 are poured, agitation for 1 minute, then rinsing with distilled water;

placing the substrate (with layers 4, 3) in a last tub, in which the contents of solutions nos. 3 and 4 are poured, agitation for 2 minutes, then rinsing with distilled water.

The sixth step illustrated in FIG. 7f includes removing the photoresist via a wet chemical method with an acetone solvent and using ultrasound.

The electroconductive support is next preferably submerged in a solution of H₂O:H₂O₂:NH₃ (500:20:1) for 3 to 5 minutes at ambient temperature in order to eliminate silver protuberances. This chemical treatment is particularly recommended in the case of an under-flush grid with H less than 100 nm, or when the grid is over-flush.

The seventh step illustrated in FIG. 7g includes depositing the electroconductive coating 5 by cathode sputtering. For example no. 1, this is a layer of indium tin oxide ITO. The ITO is deposited by magnetron cathode sputtering under a mixture of argon and oxygen O₂/(Ar+O₂) at 1% of a pressure of 2×10⁻³ mbar with a ceramic target made from indium oxide (90% by weight) and tin oxide (10% by weight).

Alternatively, AZO, GZO or AGZO is chosen. Alternatively, it involves wet chemical deposition of these materials, or even of a conductive polymer with or without metal nanowires.

A first annealing is next done at 150° C. for 30 minutes.

The eighth step includes:

depositing a layer 6a made from positive photoresist which is, for example no. 1, a photosensitive polyimide (Toray, polyimide series-DL 1600), by spin coating, covering the electroconductive coating 5, followed by a step for annealing in a convection oven (100° C., 20 minutes)

exposure to ultraviolet illustrated in FIG. 7h using an ultraviolet source that is, for example no. 1, an Hg lamp, at 20 mW/cm² (at 355 nm) on the side of the second main face 12.

The ninth step illustrated in FIG. 7i includes the result of the development of the positive photoresist in a solution with a base of tetramethylammonium hydroxide (TMAH) and a step for rinsing in deionized water until the polyimide layer 6 is made discontinuous, leaving the unexposed polyimide (due to the notching by the silver strand) in the zones of the electroconductive coating 5 located above the silver strands 20.

The polyimide passivation layer forming the insulating grid 6 is located at a thickness of approximately 300 nm.

A second annealing is next done at 170° C. for 60 minutes, with or without eliminating the first annealing. After the second annealing, the thickness of the polyimide passivation layer decreases from 380 nm to 300 nm.

The electroconductive support according to an embodiment of the invention thus makes it possible to manufacture large OLEDs (by obtaining a low sheet resistance) with a better light efficacy (via the presence of the extraction layer and a decrease in the ohmic loss caused by the low sheet resistance), without deteriorating the leakage current (and therefore the lifetime of the OLED), due to the passivation of the metal grid.

FIG. 1d illustrates a direct detail view of a section of a cavity of the first partially structured layer with the strand of a grid deposited by PVD in a comparative example done by the Applicant, showing the top surface 34 and the strand anchored in a first structured high index layer (as in example no. 1).

The silver is deposited by magnetron cathode sputtering under argon at a pressure of 8 10⁻³ mbar with a silver target.

By shadow effect due to the masking layer, the side zones 22″a and 22″b of the strand are basin-shaped. These basins generate leakage current.

The side zones 22″a and 22″b create morphological ruptures generating the currents.

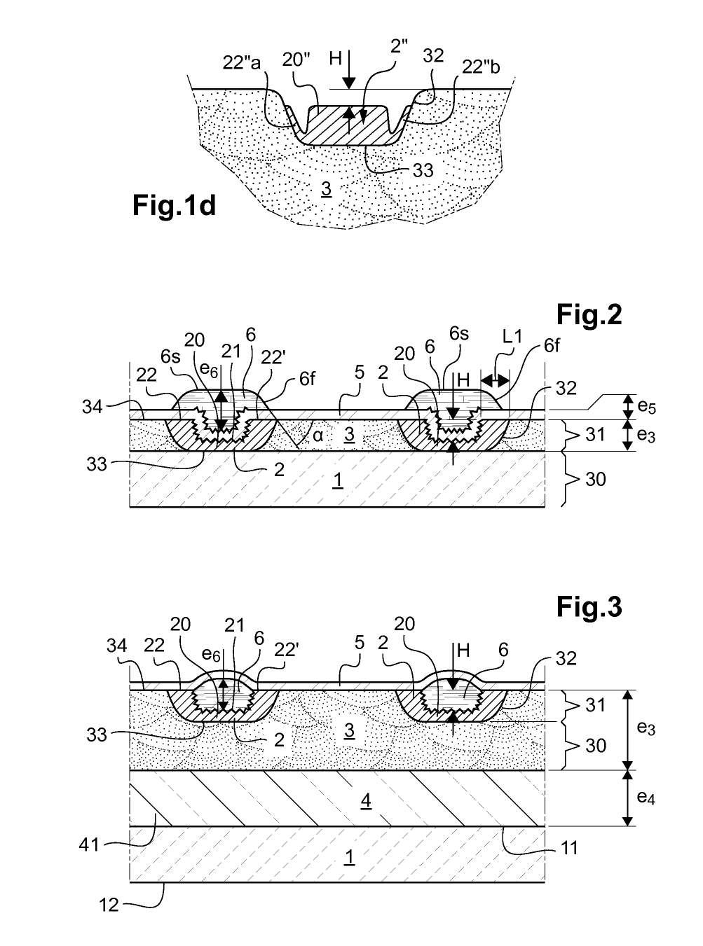

FIG. 2 is a diagrammatic sectional view of an electroconductive support for an OLED according to a second embodiment of the invention, in which the first layer 3 is completely structured and the sublayer is eliminated. The manufacturing conditions of example 1 are modified by the etching duration of the first high index layers so that e_{c} is decreased from 350 nm to 400 nm.

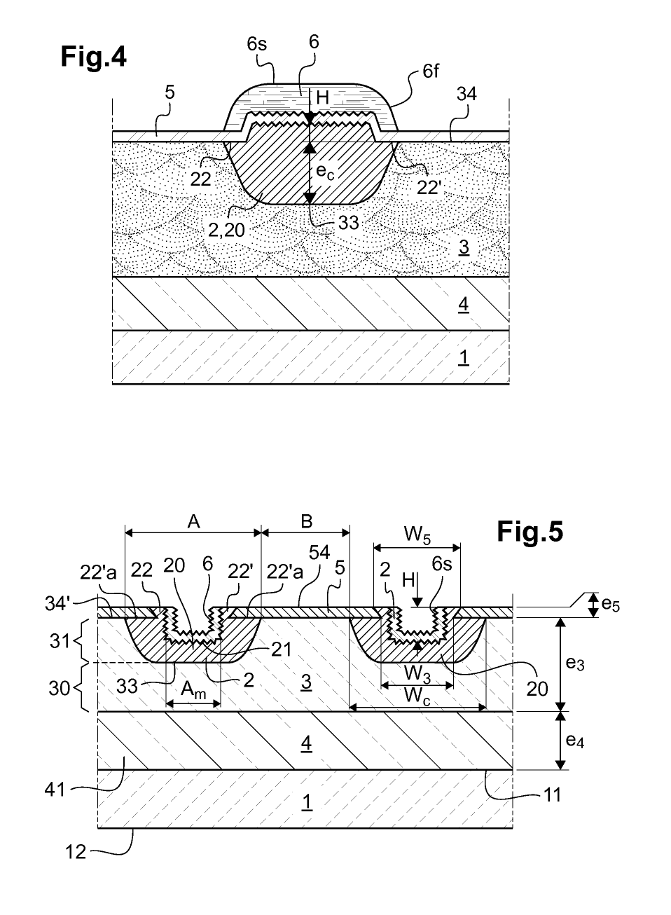

FIG. 3 is a diagrammatic sectional view of an electroconductive support for an OLED according to a third embodiment of the invention in which the passivation 6 is between the central zone 21 and the electroconductive coating 5.

FIG. 4 is a diagrammatic sectional view of an electroconductive support for an OLED according to a fourth embodiment of the invention that differs from the first embodiment in that the central strand zone is over-flush with the top surface 34. The manufacturing conditions of example 1 are modified by the etching duration of the first high index layers so that e_{c} decreases from 350 nm to 250 nm.

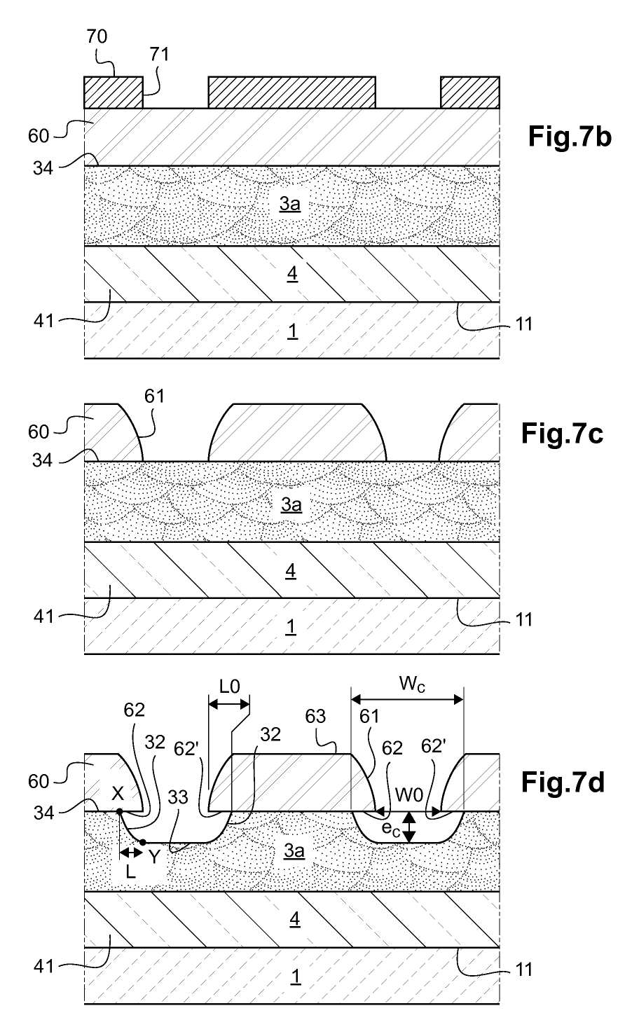

FIG. 5 is a diagrammatic sectional view of the electroconductive support for an OLED according to a fifth embodiment of the invention in which the grid is flush with the surface of the discontinuous electroconductive coating while being absent from the central zone 21. The coating has been deposited before the formation of the metal grid and the passivation layer, the discontinuity being able to be done by wet etching.

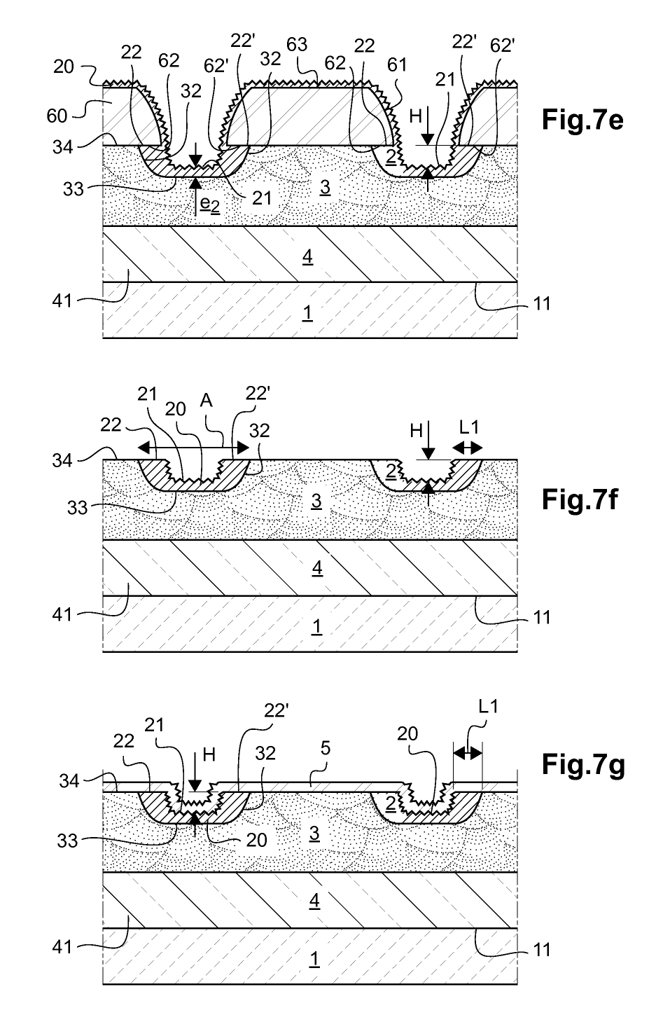

FIG. 6 is a diagrammatic sectional view of an electroconductive support for an OLED according to a sixth embodiment of the invention that differs from the first embodiment in that the grid 2, still deposited by electroless deposition such as silvering, is anchored in the first partially structured layer and also in a structured overlayer 3′ on the first layer 3.

The top surface of the non-electroconductive domains between the silver strand being the surface of the overlayer 34′, H is then defined between the surface of the central zone of the strand 21 and the surface of the overlayer 34′.

The overlayer 3′, made from an electrically insulating and preferably mineral material, is structured and discontinuous defining through holes, with a thickness e_{z} from 20 to 100 nm.

At the interface 34 (interface between the overlayer 3′ and the first layer 3), the through holes have a width W1 with Wc>W1.

Strand zones called edge zones 22a, 22′a, are adjacent to the side zones 22, 22′ and are more peripheral than the side zones, and are in the cavities below the overlayer thus flush with the surface 34 of the first layer 3.

As shown with a detailed view in FIG. 6′:

the side zones 22, 22′ have a width L1 defined as the distance between the points X″ and Y′,

the edge zones 22a, 22′a have width L2 defined as the distance between the points X′ and Y,

L3 is the distance between X″ and Y″, Y″ being the orthogonal projection of Y in the plane of the surface of the side zones 22, 22′.

L3 is greater than the total height e_{c}+e′_{c} and L3≦2(e_{c}+e′_{c}) where e_{c} is the height of the cavities and e′_{c} is the height of the holes of the overlayer 3.

In one example, the first layer is a layer of titanium oxide measuring 400 nm and the overlayer is a layer of silicon oxide with a thickness e_{z} equal to 30 nm, for example deposited by PVD or sol gel, or alternatively a layer of silica that is as fine as possible. This may be a multilayer. Generally, e_{c} is greater than e′_{c} (e_{z}).

The overlayer preferably resists the etching solution of the electroconductive coating such as ITO (during “patterning”), such as aqua regia. It forms a protective layer for the first layer.

Many different aspects and embodiments are possible. Some of those aspects and embodiments are described below. After reading this specification, skilled artisans will appreciate that those aspects and embodiments are only illustrative and do not limit the scope of the present invention. Exemplary embodiments may be in accordance with any one or more of the ones as listed below.

### Embodiment 1

An electroconductive support (100) for an OLED, including:
a plastic substrate (1), with refractive index n₁ in a range from 1.45 to 1.8, with a first main face (11), called first surface,
an electrode, supported by the plastic substrate and on the side of the first surface (11), said electrode including a layer arranged in a grid (2), called metal grid, made from metal material(s) having a sheet resistance of less than 20Ω/□, a thickness e2 of at least 100 nm, the grid being formed from strands (20), the strands having a width A of less than or equal to 50 μm and being separated by an inter-strand distance B less than or equal to 5000 μm and at least 50 μm, said strands being separated by a plurality of non-electrically insulating non-electroconductive domains (31, 3′) having a top surface (34,34′) further from the substrate,

characterized in that on the side of the first surface (11), the electroconductive support includes a first layer, preferably electrically insulating, with a given composition, with a refractive index n₃ of 1.7 to 2.3, the first layer being directly on the first surface or on a moisture barrier layer (4), mineral, the first layer being partially or completely structured in terms of thickness with through holes or cavities, with a width Wc to at least partially anchor the metal grid, the top surface being the surface of the first layer or the surface of an overlayer, mineral, on the first layer, in that the strands (20) have, along their length, a central zone (21) between side zones (22, 22′) that are flush with the top surface (34, 34′) and the surface roughness of the central zone (21) is greater than the surface roughness of the side zones (22, 22′),

in that the support further comprises:
an electroconductive coating (5) made from an organic or mineral material that covers the top surface (34, 34′), is above the side zones and electrically connected with the side zones, optionally is present above the central zones and electrically connected with central zones (2), with a thickness e₅ less than or equal to 800 nm, with a resistivity ρ₅ of less than 20 Ω·cm and greater than the resistivity of the metal grid, and which has a refractive index n₅ of at least 1.5,
   and in the in the central zone (21), the middle of the strand surface (20) and the top surface are separated by a vertical distance H taken at the normal to the first surface (11) and which is less than or equal to 500 nm.

### Embodiment 2

The electroconductive support (100) according to the preceding Embodiment, characterized in that the roughness parameter Rq of the side zones (22, 22′) is no more than 5 nm.

### Embodiment 3

The electroconductive support (100) according to the preceding Embodiment, characterized in that it comprises a discontinuous passivation layer (6), made from an electrically insulating material, forming a grid of isolating tracks located above the central zones (21) and optionally above the side zones (22, 22′) of the strands, not protruding laterally from the outer edges of the strands or protruding laterally from the outer edges of the strands by no more than 1 μm.

### Embodiment 4

The electroconductive support (100) according to Embodiment 3, characterized in that the passivation layer (6) has, above the central zone (21), a upper surface (6s), which has a roughness parameter Rq of less than 10 nm.

### Embodiment 5

The electroconductive support (100) according to one of Embodiments 3 or 4, characterized in that the passivation layer (6) is an oxide layer preferably by sol gel and/or a nitride of a material that is a metal and/or silicon and preferably a layer of silicon or titanium nitride, or titanium, zirconium, silicon, niobium oxide, and mixtures thereof.

### Embodiment 6

The electroconductive support (100) according to one of Embodiments 1 to 5, characterized in that the electroconductive coating is discontinuous, missing from the central zones, and H is then defined between the middle of the strand surface (20) and the surface of the electroconductive coating.

### Embodiment 7

The electroconductive support (100) according to one of Embodiments 3 or 4, characterized in that the electrically insulating material is a positive photoresist, with a thickness e₆ of less than 1000 nm, on the electroconductive coating with a base of at least one of the following materials: polyimide, polysiloxane, phenol formaldehyde, polymethyl methacrylate.

### Embodiment 8

The electroconductive support (100) according to one of Embodiments 3 or 4, characterized in that the passivation layer is between the central zone and the electroconductive coating.

### Embodiment 9

The electroconductive support (100) according to one of the preceding Embodiments, characterized in that the first electrically insulating layer is an oxide layer, preferably by sol gel, and/or nitride of a material that is a metal and/or silicon, and preferably a layer of silicon or titanium nitride, or titanium, zirconium, silicon or niobium oxide and mixtures thereof, or is a layer of conductive transparent oxide.

### Embodiment 10

The electroconductive support (100 to 200) according to one of the preceding Embodiments, characterized in that the plastic is a thermoplastic film, preferably a PEN.

### Embodiment 11

The electroconductive support (100) according to one of the preceding Embodiments, characterized in that the central zone (21) is under-flush with the top surface (34, 34′) and H is greater than 100 nm, even greater than 150 nm.

### Embodiment 12

The electroconductive support (100) according to one of the Embodiments 1 to 10, characterized in that H is less than or equal to 100 nm, and even preferably the central zone is under-flush with the top surface, preferably the metal strand surface (20) is stripped of protuberances with a height greater than 10 nm running on the inner edges of the side zones (22, 22).

### Embodiment 13

The electroconductive support (100) according to one of the preceding Embodiments, characterized in that the metal grid (2, 20) is obtained by electroless deposition, and preferably by silvering.

### Embodiment 14

The electroconductive support (100) according to one of the preceding Embodiments, characterized in that the metal grid (2, 20), preferably made from silver, has a coverage rate T of less than 25%, or less than 10%, and even less than 6%.

### Embodiment 15

The electroconductive support (100) according to one of the preceding Embodiments, characterized in that the thickness e₂ of the metal grid (2, 20) is less than 1500 nm, preferably in a range from 100 nm to 1000 nm, and in particular in a range from 200 nm to 800 nm, the width A is less than 30 μm, preferably in a range from 1.5 μm to 20 μm.

### Embodiment 16

The electroconductive support (100) according to one of the preceding Embodiments, characterized in that the electroconductive coating (5) comprises a mineral layer with a refractive index nₐ between 1.7 and 2.3, with a thickness of less than 150 nm, made from an electroconductive transparent oxide, preferably with a base of indium tin oxide or a base of zinc oxide.

### Embodiment 17

The electroconductive support (100) according to one of Embodiments 1 to 16, characterized in that the first layer is completely structured (3) in terms of thickness with through holes with a width Wc, preferably any barrier sub-layer is not structure.

### Embodiment 18

The electroconductive support (100) according to one of Embodiments 1 to 16, characterized in that the first layer (3) is partially structured in terms of its thickness, while being made up of:
a region (30), called lower region, below the metal grid,
a structured region (31), that region forming the non-electroconductive domains and with cavities with width Wc, and preferably the side zones are adjacent to the first layer and have a width L1, L1 being greater than the height e_{c} of the cavities and L1≦2e_{c} and L1≦1.4e_{c}.

### Embodiment 19

The electroconductive support (100) according to one of Embodiments 1 to 16, characterized in that the non-electroconductive layers include:
the overlayer (3′), made from an electrically insulating material, preferably mineral, that is discontinuous defining through holes, the overlayer being part of the non-electroconductive domains, and preferably at least 20 nm,
the first layer, which is preferably electrically insulating, preferably mineral, which is:
   entirely structured (3) in terms of thickness, with through holes with a width Wc at the interface between the overlayer and the first layer,
   or partially structured (3) in terms of thickness, being made up of:
      a region (30), called lower region, below the metal grid,
      a structured region (31), below the overlayer, region with cavities across from the through holes, with a width Wc at the interface between the over-layer and the first layer,
         at the interface between the overlayer and the first layer, the through holes having a width W1, preferably with Wc≧1, when Wc>W1 of the strand zones, called edge zones (22a, 22′a), are adjacent to the side zones, are more peripheral than the side zones, and are in the cavities of the overlayer,
         when Wc>W1, the side zones have a width L1 defined as the distance between points X″ and Y′, the edge zones with width L2 defined as the distance between points X′ and Y, Y″ is the orthogonal projection of Y in the plane of the surface of the side zones (22, 22′), L3 is the distance between X″ and Y″, L3 being greater than the total height e_{c}+e′_{c} and L3≦2(e_{c}+e′_{c}), where e_{c} is the height of the cavities (taken in the middle) and e′_{c} is the height of the holes.

### Embodiment 20

An organic light-emitting device incorporating an electroconductive support (100) according to Embodiments 1 to 20, the electrode with the metal grid (2) forming the lower electrode, closest to the first surface (11) of the substrate.

### Embodiment 21

A method for manufacturing an electroconductive support (100) according to one of the preceding Embodiments, characterized in that it includes the following steps, in the following order:
providing the substrate (1), including, in the following order:
a potential sub-layer forming a moisture barrier on the first surface (11),
a high index continuous layer (3a), made from the composition with a refractive index n₃ of the first layer,
the formation of cavities or through holes in the high index layer (3a), thereby forming a first layer with a structured thickness (3) whereof the surface is the top surface (34), that formation including:
   producing, on the high index layer (3a), a discontinuous masking layer (60) made from a photoresist with a given arrangement of through openings, with flanks (61), in particular for:
   solid layer deposition of the photoresist
   exposure to the ultraviolet using an ultraviolet source on the side of the first surface (11),
   wet etching of the high index layer (3a), through the through openings of the masking layer, creating zones of the masking layer suspended above the cavities or through holes and thus defining surface portions called inner surfaces (62, 62′) of the masking layer (60) across from the cavities (32, 33) or through holes,
forming the metal grid (2) comprising a liquid deposition, preferably electroless, of a first metal material of the grid in the cavities or through holes, the first material being deposited on the flanks (32) of the cavities or the through holes and completely on the inner surfaces (62, 62′) of the masking layer (60), thereby forming the side strand zones (22, 22′) flush with the top surface (34) and less rough than the central zones of the strand (21),
removing the masking layer (60), in particular by liquid means.
preferably, forming the insulating grid passivation layer by insulating tracks above the central zones of the strands, preferably on the electroconductive coating present on the central zones.

### Embodiment 22

A method for manufacturing an electroconductive support (100) according to one of the preceding electroconductive support Embodiments, characterized in that it includes the following steps, in the following order:
providing the substrate (1), comprising:
   an optional moisture sub-barrier layer on the first surface (11),
   a continuous high index layer (3a), made from the composition with a refractive index n₃ of the first layer,
   on the high index layer (3a), an electrically insulating continuous layer called additional layer (3′a), made from the material of the overlayer (3′),
forming blind or through openings in the additional layer (3′a), thereby forming the overlayer (3′) whereof the thickness is completely or partially structured, that formation including:
   producing, on the additional layer (3′a), a masking layer made from a discontinuous photoresist (60) with a given arrangement of through openings, and with flanks, in particular by
   solid layer deposition of the photoresist,
   exposure to ultraviolet using an ultraviolet source on the side of the first surface (11),
wet etching of the additional layer (3′a), with a first etching solution, through the through openings (61) of the masking layer, creating zones of the masking layer suspended above blind or through holes and thus defining surface portions, called inner surfaces (62, 62′), of the masking layer across from the blind or through holes,
forming cavities or through holes in the high index layer (3a), thereby forming the first partially structured layer (3) with Wc>W1, that formation including:
   wet etching of the high index layer (3a), with a second etching solution, preferably different from the first solution and preferably not etching the overlayer, through the through openings of the masking layer, through holes of the overlayer, creating zones of the masking layer (60) and the overlayer suspended above the cavities or through holes of the first layer and thereby defining surface portions called other inner surfaces (22a, 22′a) of the overlayer across from the cavities or through holes of the first layer,
forming the metal grid (2) comprising a liquid deposition, preferably electroless, of a first metal material of the grid in the through cavities or holes of the first layer and in the through holes of the overlayer, thereby forming the side strand zones flush with the top surface (34′) below the inner surfaces (62, 62′) while being less rough than the central zones of the strand (21), the first material being deposited on the flanks of the through holes of the overlayer, completely on the other inner surfaces (22a, 22a) of the overlayer (3), on the inner surfaces (62, 62′) of the masking layer (60), thereby forming the edge zones (22a, 22′a) and side strand zones (22, 22′),
removing the masking layer (60), in particular by liquid means,
preferably, forming the insulating grid passivation layer formed from insulating tracks above the central zones of the strands, preferably on the electroconductive coating present on the central zones.

### Embodiment 23

The method for manufacturing the electroconductive support (100) according to one of the preceding method Embodiments, characterized in that the liquid deposition of the first metal material is silvering, and preferably the grid (2) is a single layer.

### Embodiment 24

The method for manufacturing the electroconductive support (100) according to one of the preceding method Embodiments, characterized in that the formation of the insulating grid passivation layer formed from insulating tracks on the central zones of the strands includes:
solid layer deposition of the positive photoresist of the passivation layer (6) covering the electroconductive coating,
the exposure to the ultraviolet using an ultraviolet source on the side of the second main face (12),
development in solution until the layer of positive photoresist is made to discontinuous, the positive photoresist remaining localized above the metal grid (2) to form the passivation layer (6).

### Embodiment 25

The method for manufacturing the electroconductive support (100) according to one of the preceding method Embodiments, characterized in that in particular, when H is no more than 100 nm, the removal of the masking layer (60) following the formation of the metal grid creates metal protuberances with a height of at least 10 nm running along the inner edges of the side zones (22, 22′) of the metal grid, and the method comprises, after the removal of the masking layer (60) and before the deposition of the electroconductive layer, a step for wet etching to eliminate the protuberances.

### Embodiment 26

The method for manufacturing the electroconductive support (100) according to one of the preceding method Embodiments, characterized in that the liquid deposition of the first metal material is silvering, and the grid (2) is preferably a single layer.

### Embodiment 27

The method for manufacturing the electroconductive support (100 to 200) according to one of the preceding method Embodiments, characterized in that it comprises, before depositing the electroconductive coating (5), a step for heating to a temperature below 200° C., preferably between 150° C. and 180° C., for a duration preferably between 5 minutes and 120 minutes, and in particular between 15 and 90 minutes and/or in that it comprises, after the deposition of the electroconductive coating, preferably mineral, before or after the deposition of the passivation layer, a step for heating to a temperature below 200° C., preferably between 150° C. and 180° C., for a duration preferably between 5 minutes and 120 minutes, in particular between 15 and 90 minutes.

### Embodiment 28

An electroconductive support comprising:
a first layer having a primary surface and defining a cavity extending from the primary surface;
a conductive strand within the cavity of the first layer, wherein the conductive strand has an upper surface within a central zone and a side zone, wherein:
the primary surface of the first insulating layer is closer to the side zone than to the central zone; and
the upper surface has a surface roughness within the central zone that is rougher than a surface roughness within the side zone; and
an electroconductive layer overlying the conductive strand and the first layer, wherein the electroconductive layer contacts the conductive strand along the upper surface of the conductive strand within the side zone.

### Embodiment 29

The electroconductive support of Embodiment 28, where the surface roughness within the central zone is at least 5%, at least 10%, at least 50%, or at least 100% greater than the surface roughness within the side zone.

### Embodiment 30

The electroconductive support of Embodiment 28 or 29, wherein a roughness parameter Rq of the side zone is at most 5 nm, at most 3 nm, at most 2 nm, or at most 1 nm.

### Embodiment 31

The electroconductive support of any one of Embodiments 28 to 30, wherein the roughness parameter Rq of the central zone is at least 10 nm, at least 20 nm, or at least 60 nm.

### Embodiment 32

The electroconductive support of any one of Embodiments 28 to 31, wherein the upper surface of the conductive strand within the central zone is at a different elevation as compared to the upper surface of the conductive strand within the side zone.

### Embodiment 33

The electroconductive support of any one of Embodiments 28 to 32, further comprising a passivation layer, wherein the electroconductive layer is disposed between the first layer and the conductive strand, and the electroconductive layer contacts the central zone of the conductive strand; or the passivation layer is disposed between the conductive strand and the electroconductive layer, and the passivation layer contacts the central zone of the conductive strand.

### Embodiment 34

The electroconductive support of Embodiment 33, wherein the passivation layer has a width that is no greater than 1.9, no greater than 1.5, no greater than 1.1, or no greater than 0.99 times a width of the conductive strand.

### Embodiment 35

The electroconductive support of any one of Embodiments 28 to 34, wherein the electroconductive layer includes a transparent conductive oxide.

### Embodiment 36

The electroconductive support of any one of Embodiments 28 to 35, further comprising a substrate, wherein the first layer has a refractive index that is higher as compared to the substrate.

### Embodiment 37

The electroconductive support of any one of Embodiments 28 to 36, further comprising a substrate and a moisture barrier disposed between the substrate and the first layer.

### Embodiment 38

The electroconductive support of any one of Embodiments 28 to 37, wherein the conductive strand is part of a conductive grid.

### Embodiment 39

An organic light-emitting device including the electroconductive support of any one of Embodiments 28 to 38.

### Embodiment 40

A method of forming an electroconductive support comprising:
forming a patterned masking layer over a first layer having a primary surface, wherein the patterned masking layer includes an opening;
etching a cavity in the first layer below the opening such that a zone of the patterned masking layer is suspended over the cavity;
depositing a conductive material within the cavity using a wet chemical deposition; and
removing the patterned masking layer to form a conductive strand within the cavity, wherein the conductive strand has a side zone and a central zone, the side zone is defined by a portion of the conductive strand that was covered by the zone of the patterned masking layer, and the central zone was under the opening in the patterned masking layer when depositing the conductive material; and
forming an electroconductive layer overlying the conductive strand and the first layer, wherein the electroconductive layer contacts the first layer and the conductive strand along the upper surface of the conductive strand within the side zone.

### Embodiment 41

The method of Embodiment 40, further comprising:
forming a passivation layer over the conductive strand;
selectively exposing the passivation layer to radiation, wherein the conductive strand acts as a mask, such that part of the passivation layer overlying the conductive strand is not exposed to the radiation; and
removing an exposed portion of the passivation layer and leaving a remaining portion of the passivation layer.

### Embodiment 42

A method of forming an electroconductive support comprising:
forming a patterned masking layer over a first layer having a primary surface, wherein the patterned masking layer includes an opening;
etching a cavity in the first layer below the opening such that a zone of the patterned masking layer is suspended over the cavity;
depositing a conductive material within the cavity using a wet chemical deposition; and
removing the patterned masking layer to form a conductive strand within the cavity, wherein the conductive strand has a side zone and a central zone, the side zone is defined by a portion of the conductive strand that was covered by the zone of the patterned masking layer, and the central zone was under the opening in the patterned masking layer when depositing the conductive material;
forming a passivation layer over the conductive strand;
selectively exposing the passivation layer to radiation, wherein the conductive strand acts as a masking layer, such that part of the passivation layer overlying the conductive strand is not exposed to the radiation; and
removing an exposed portion of the passivation layer and leaving a remaining portion of the passivation layer.

### Embodiment 43

The method of any one of Embodiments 40 to 42, wherein depositing the conductive material is performed using electroless plating.

### Embodiment 44

The method of any one of Embodiments 40 to 43, wherein an upper surface of the conductive strand has a surface roughness within central zone that is rougher than a surface roughness within the side zone.

### Embodiment 45

The method of any one of Embodiments 40 to 44, further comprising forming a passivation layer after forming the electroconductive layer.

### Embodiment 46

The method of any one of Embodiments 40 to 44, further comprising forming a passivation layer, wherein the forming the electroconductive layer is performed after forming the passivation layer.

### Embodiment 47

The method of any one of Embodiments 40 to 46, wherein removing the patterned masking layer also removes the conductive material that overlies the patterned masking layer.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. An electroconductive support comprising:
a first layer having a primary surface and defining a cavity extending from the primary surface;
a conductive strand within the cavity of the first layer, wherein the conductive strand has an upper surface within a central zone and a side zone, wherein:
the primary surface of the first insulating layer is closer to the side zone than to the central zone; and
the upper surface has a surface roughness within the central zone that is rougher than a surface roughness within the side zone; and
an electroconductive layer overlying the conductive strand and the first layer, wherein the electroconductive layer contacts the conductive strand along the upper surface of the conductive strand within the side zone.

2. The electroconductive support of claim 1, where the surface roughness within the central zone is at least 5% greater than the surface roughness within the side zone.

3. The electroconductive support of claim 1, wherein a roughness parameter Rq of the side zone is at most 5 nm.

4. The electroconductive support of claim 3, wherein the roughness parameter Rq of the central zone is at least 10 nm.

5. The electroconductive support of claim 1, wherein the upper surface of the conductive strand within the central zone is at a different elevation as compared to the upper surface of the conductive strand within the side zone.

6. The electroconductive support of claim 1, further comprising a passivation layer, wherein:
the electroconductive layer is disposed between the first layer and the conductive strand, and the electroconductive layer contacts the central zone of the conductive strand; or
the passivation layer is disposed between the conductive strand and the electroconductive layer, and the passivation layer contacts the central zone of the conductive strand.

7. The electroconductive support of claim 6, wherein the passivation layer has a width that is no greater than 1.9 times a width of the conductive strand.

8. The electroconductive support of claim 1, wherein the electroconductive layer includes a transparent conductive oxide.

9. The electroconductive support of claim 1, further comprising a substrate, wherein the first layer has a refractive index that is higher as compared to the substrate.

10. The electroconductive support of claim 1, further comprising a substrate and a moisture barrier disposed between the substrate and the first layer.

11. The electroconductive support of claim 1, wherein the conductive strand is part of a conductive grid.

12. An organic light-emitting device including the electroconductive support of claim 1.

13. A method of forming an electroconductive support comprising:
forming a patterned masking layer over a first layer having a primary surface, wherein the patterned masking layer includes an opening;
etching a cavity in the first layer below the opening such that a zone of the patterned masking layer is suspended over the cavity;
depositing a conductive material within the cavity using a wet chemical deposition; and
removing the patterned masking layer to form a conductive strand within the cavity, wherein the conductive strand has a side zone and a central zone, the side zone is defined by a portion of the conductive strand that was covered by the zone of the patterned masking layer, and the central zone was under the opening in the patterned masking layer when depositing the conductive material; and
forming an electroconductive layer overlying the conductive strand and the first layer, wherein the electroconductive layer contacts the first layer and the conductive strand along the upper surface of the conductive strand within the side zone.

14. The method of claim 13, wherein depositing the conductive material is performed using electroless plating.

15. The method of claim 13, wherein an upper surface of the conductive strand has a surface roughness within central zone that is rougher than a surface roughness within the side zone.

16. The method of claim 13, further comprising forming a passivation layer after forming the electroconductive layer.

17. The method of claim 13, further comprising forming a passivation layer, wherein the forming the electroconductive layer is performed after forming the passivation layer.

18. The method of claim 13, wherein removing the patterned masking layer also removes the conductive material that overlies the patterned masking layer.

19. The method of claim 13, further comprising:
forming a passivation layer over the conductive strand;
selectively exposing the passivation layer to radiation, wherein the conductive strand acts as a mask, such that part of the passivation layer overlying the conductive strand is not exposed to the radiation; and
removing an exposed portion of the passivation layer and leaving a remaining portion of the passivation layer.

20. A method of forming an electroconductive support comprising:
forming a patterned masking layer over a first layer having a primary surface, wherein the patterned masking layer includes an opening;
etching a cavity in the first layer below the opening such that a zone of the patterned masking layer is suspended over the cavity;
depositing a conductive material within the cavity using a wet chemical deposition; and
removing the patterned masking layer to form a conductive strand within the cavity, wherein the conductive strand has a side zone and a central zone, the side zone is defined by a portion of the conductive strand that was covered by the zone of the patterned masking layer, and the central zone was under the opening in the patterned masking layer when depositing the conductive material;
forming a passivation layer over the conductive strand;
selectively exposing the passivation layer to radiation, wherein the conductive strand acts as a masking layer, such that part of the passivation layer overlying the conductive strand is not exposed to the radiation; and
removing an exposed portion of the passivation layer and leaving a remaining portion of the passivation layer.
